(19) United States
(12) Patent Application Publication
(10) Pub. No.: US 2025/0079227 A1
(43) Pub. Date: Mar. 6, 2025

(54) WAFER RETAINING DEVICE

(71) Applicant: Taiwan Semiconductor Manufacturing Company Limited, Hsin-Chu (TW)

(72) Inventors: Lu-Hsun LIN, Hsinchu County (TW); Tsung-Min LIN, Zhubei City (TW); Chin Tsung LIN, Camas, WA (US); Hsiao-Yin HSIEH, Zhubei City (TW); Po-Tang TSENG, Hsinchu County (TW)

(21) Appl. No.: 18/415,751

(22) Filed: Jan. 18, 2024

Related U.S. Application Data
(60) Provisional application No. 63/536,528, filed on Sep. 5, 2023.

(51) Int. Cl. H01L 21/687; H01L 21/67

(52) U.S. Cl. CPC H01L 21/68721; H01L 21/67253; H01L 21/68728

(57) ABSTRACT

A wafer retaining device is provided. The wafer retaining device includes a platen configured to support a semiconductor wafer, and a retainer assembly. The retainer assembly includes a mounting member coupled to the platen, a lever, and a biasing member including a first end coupled to the lever and a second end coupled to the mounting member. The biasing member is configured to bias the lever to a closed position relative to the platen. The lever inhibits movement of the semiconductor wafer when the lever is in the closed position.

### RELATED APPLICATION

This application claims priority to U.S. provisional application 63/536,528, titled “SUBSTRATE RETAINING DEVICE” and filed on Sep. 5, 2023, which is incorporated herein by reference.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a side view of a wafer retaining device, in accordance with some embodiments.

FIG. 2A illustrates a wafer retaining device in a closed state, in accordance with some embodiments.

FIG. 2B illustrates a wafer retaining device during transition from a closed state to an open state, in accordance with some embodiments.

FIG. 2C illustrates a wafer retaining device in an open state, in accordance with some embodiments.

FIG. 2D illustrates a semiconductor wafer positioned relative to a wafer retaining device in an open state, in accordance with some embodiments.

FIG. 2E illustrates a semiconductor wafer retained by a wafer retaining device in a closed state, in accordance with some embodiments.

FIG. 3 illustrates a perspective view of a portion of a wafer retaining device, in accordance with some embodiments.

FIG. 4 illustrates a top view of a wafer retaining device when a semiconductor wafer is retained by the wafer retaining device, in accordance with some embodiments.

FIG. 5A illustrates a top view of a wafer retaining device, in accordance with some embodiments.

FIG. 5B illustrates a top view of a wafer retaining device, in accordance with some embodiments.

FIG. 6 illustrates a cross-sectional view of a portion of a semiconductor wafer comprising an edge of the semiconductor wafer, in accordance with some embodiments.

FIG. 7A illustrates a retainer assembly of a wafer retaining device, in accordance with some embodiments.

FIG. 7B illustrates a biasing member of a wafer retaining device, in accordance with some embodiments.

FIG. 8A illustrates a top view of a wafer retaining device in an environment comprising a handler box and/or a processing chamber, in accordance with some embodiments.

FIG. 8B illustrates a top view of a wafer retaining device in an environment comprising a handler box and/or a processing chamber, in accordance with some embodiments.

FIG. 8C illustrates a top view of a wafer retaining device in an environment comprising a handler box and/or a processing chamber, in accordance with some embodiments.

FIG. 8D illustrates a top view of a wafer retaining device in an environment comprising a handler box and/or a processing chamber, in accordance with some embodiments.

FIG. 8E illustrates a top view of a wafer retaining device in an environment comprising a handler box and/or a processing chamber, in accordance with some embodiments.

FIG. 9 illustrates a scenario associated with a semiconductor fabrication process, in accordance with some embodiments.

FIG. 10A illustrates a wafer retaining device in a closed state, in accordance with some embodiments.

FIG. 10B illustrates a wafer retaining device in an open state, in accordance with some embodiments.

FIG. 11 is a flow diagram illustrating a method of operating a wafer retaining device, in accordance with some embodiments.

FIG. 12 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

Semiconductor wafers are subjected to various processes during the fabrication of semiconductor devices. In some embodiments, a semiconductor wafer is retained by a wafer retaining device while a semiconductor fabrication process is performed on the semiconductor wafer. Some wafer retaining devices retain the semiconductor wafer using a clamp ring with clamps extending inwardly from the clamp ring and require that the semiconductor wafer be passed through a slit in the clamp ring to be retained. However, passing the semiconductor wafer through the slit increases a likelihood that the semiconductor wafer is damaged, such as at least one of scratched, chipped, etc.

In accordance with some embodiments, a wafer retaining device is provided which comprises a platen and a retainer assembly coupled to the platen. The retainer assembly comprises at least one of a mounting member, a lever, or a biasing member. In some embodiments, the retainer assembly comprises a first end coupled to the lever and a second end coupled to the mounting member. In some embodiments, the biasing member is configured to bias the lever to a closed position relative to the platen. In some embodiments, the wafer retaining device comprises a lever engagement member configured to apply a lever-opening force to the lever to move the lever from the closed position to an open position relative to the platen. In some embodiments, the semiconductor wafer is mounted relative to the wafer retaining device when the lever is in the open position, thereby providing for a reduced likelihood of the semiconductor wafer being damaged when the semiconductor wafer is mounted relative to the wafer retaining device as compared with wafer retaining devices that require the semiconductor wafer to pass through the slit defined by the clamp ring.

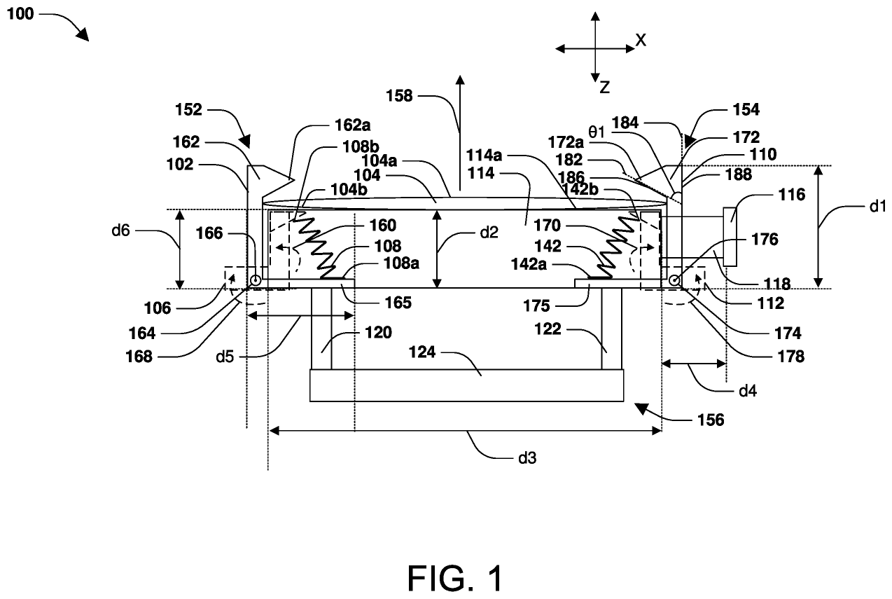

FIG. 1 illustrates a wafer retaining device 100 according to some embodiments. In some embodiments, the wafer retaining device 100 comprises at least one of a platen 114 configured to support a semiconductor wafer 104, a first retainer assembly 152, a second retainer assembly 154, a lever engagement structure 156, or one or more other components. In some embodiments, the semiconductor wafer 104 is disposed on a surface 114a of the platen 114. In some embodiments, the semiconductor wafer 104 comprises at least one of a substrate, a photomask, a semiconductor device, a die, etc. In some embodiments, the wafer retaining device 100 is configured to retain the semiconductor wafer 104 while a semiconductor fabrication process is performed on the semiconductor wafer 104.

In some embodiments, the first retainer assembly 152, such as a first clamping unit, comprises at least one of a first lever 102, a first mounting member 106 (shown with a dashed-line outline in FIG. 1), a first biasing member 108, or one or more other suitable components. In some embodiments, the first mounting member 106 is coupled to the platen 114. In some embodiments, when the first mounting member 106 is mounted to the platen 114, the first mounting member 106 has a fixed position relative to platen 114. In some embodiments, the first lever 102 is coupled to, such as pivotally coupled to, the first mounting member 106. In some embodiments, the first biasing member 108 comprises at least one of a first end 108a coupled to the first lever 102 or a second end 108b coupled to the first mounting member 106. In some embodiments, the first biasing member 108 comprises at least one of a first spring, a first solenoid (not shown), or other suitable biasing device. In some embodiments, the first lever 102 comprises at least one of a first weight region 162, a first fulcrum region 164, or a first power region 165. In some embodiments, the first fulcrum region 164 is pivotally coupled to the first mounting member 106.

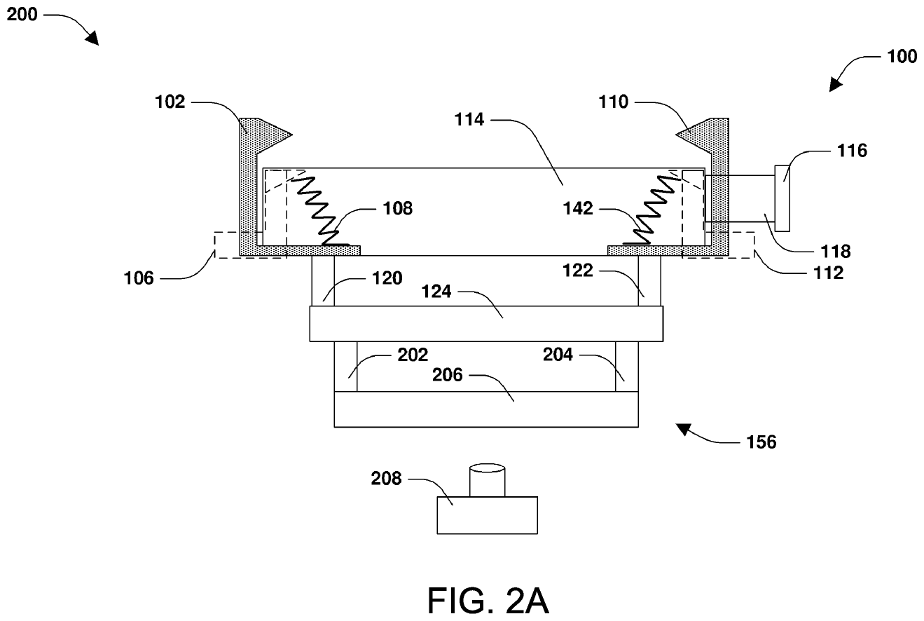

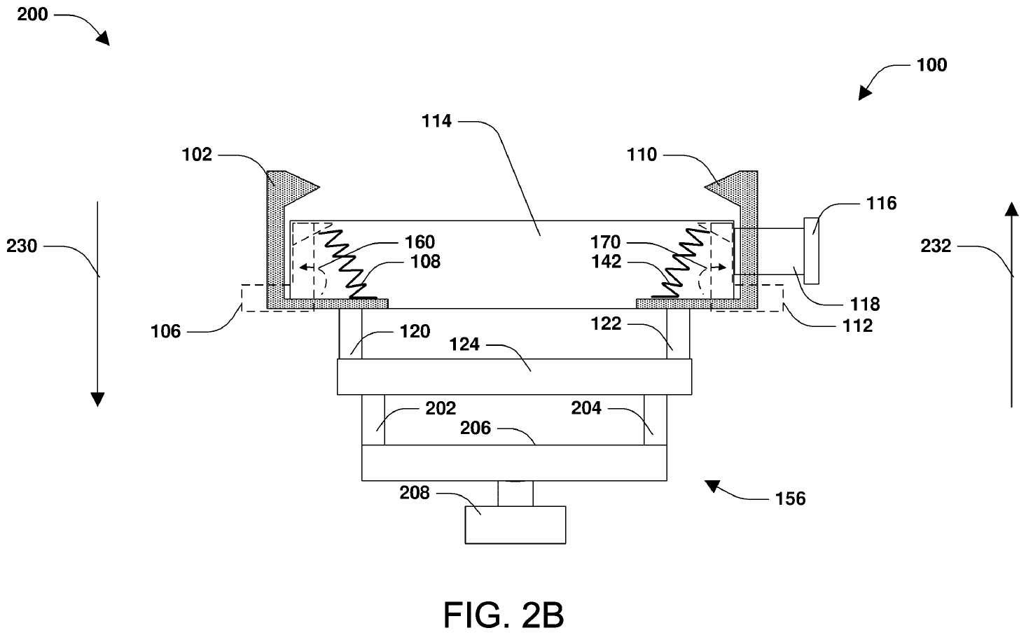

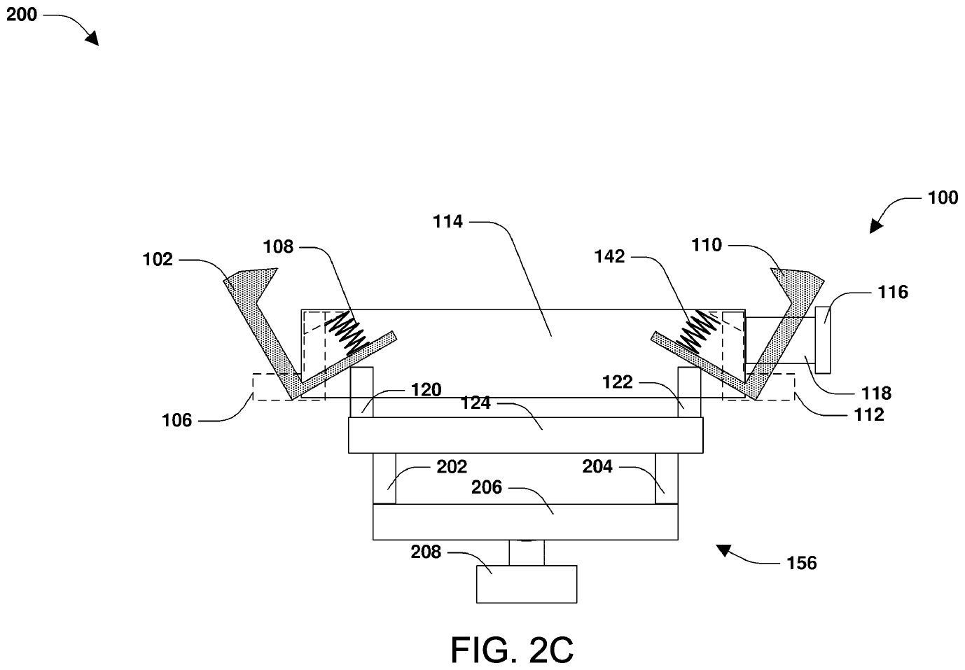

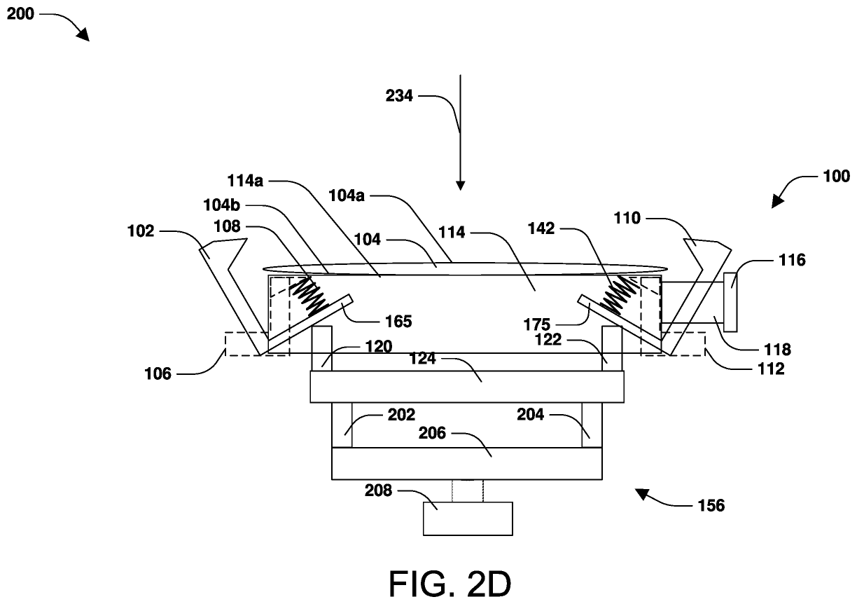

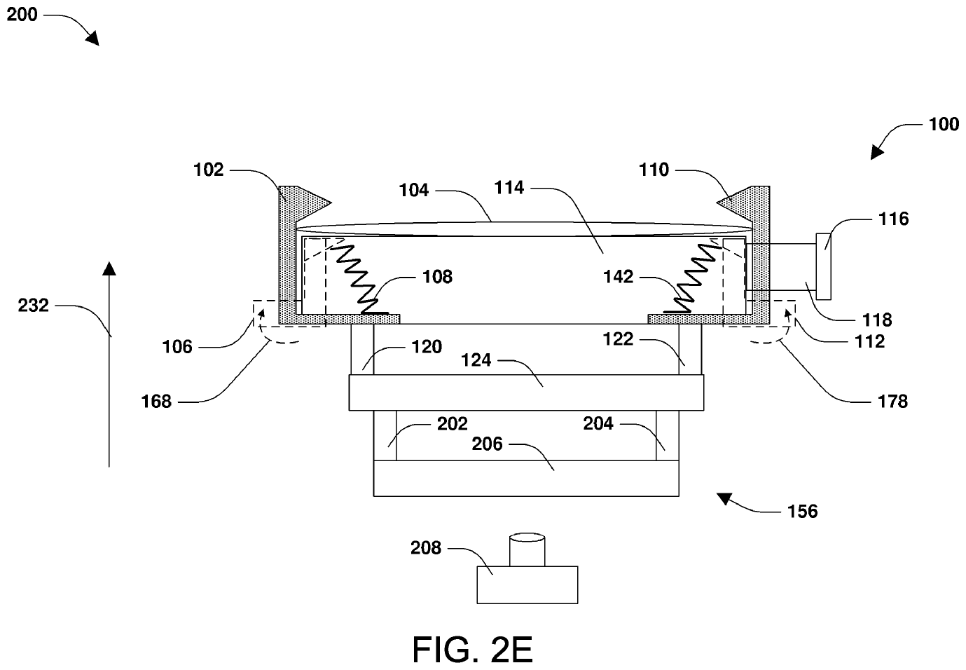

In some embodiments, the first biasing member 108 is configured to bias the first lever 102 to a first closed position relative to the platen 114. FIG. 1 depicts the first lever 102 in the first closed position in accordance with some embodiments. In some embodiments, the first lever 102 transitions between the first closed position and a first open position relative to the platen 114. FIG. 2C depicts the first lever 102 in the first open position in accordance with some embodiments. In some embodiments, the first biasing member 108 is configured to exert a first biasing force to the first lever 102. In some embodiments, the first end 108a of the first biasing member 108 is coupled to the first power region 165 of the first lever 102. In some embodiments, the first biasing member 108 exerts the first biasing force to the first power region 165 of the first lever 102 to rotate the first lever 102 in a first lever-closing direction 168 about an axis 166 through the first fulcrum region 164. In some embodiments, the axis 166 extends through a location of a first pivot (not shown) pivotally coupling the first fulcrum region 164 to the first mounting member 106. In some embodiments, the wafer retaining device 100 comprises a first hard stop object (not shown) configured to inhibit movement of the first lever 102 in the first lever-closing direction 168 past a defined position, such as the first closed position of the first lever 102 or other position of the first lever 102. Thus, in accordance with some embodiments, when the first lever 102 is in the first closed position, the first hard stop object inhibits the first lever 102 from moving (further) in the first lever-closing direction 168 even when the first biasing member 108 exerts the first biasing force to the first power region 165.

In some embodiments, the first spring of the first biasing member 108 is in an uncompressed and/or extended state when the first lever 102 is in the first open position. In some embodiments, the first spring of the first biasing member 108 is in a compressed and/or loaded state when the first lever 102 is in the first open position. Other configurations of the first spring and/or the first biasing member 108 are within the scope of the present disclosure. In some embodiments, the first biasing force is greater when the first lever 102 is in the first open position than when the first lever 102 is in the first closed position.

In some embodiments, when the first lever 102 is in the first closed position, the first lever 102 obstructs a first path of motion 158 of the semiconductor wafer 104. In some embodiments, a first protrusion 162a of the first weight region 162 overlies the semiconductor wafer 104 when the first lever 102 is in the first closed position. In some embodiments, when the first lever 102 is in the first closed position, the first lever 102 is in at least one of direct contact or indirect contact with the semiconductor wafer 104. In some embodiments, the first lever 102 is in at least one of direct contact or indirect contact with a first surface 104a of the semiconductor wafer 104 when the first lever 102 is in the first closed position. In some embodiments, the first lever 102 is in at least one of direct contact or indirect contact with an edge of the semiconductor wafer 104 when the first lever 102 is in the first closed position. In some embodiments, when the first lever 102 is in the first closed position, at least one of the first lever 102 or one or more other levers of the wafer retaining device 100 exert a wafer securing force to the semiconductor wafer 104 to secure the semiconductor wafer 104 in a target wafer position, such as the position of the semiconductor wafer 104 depicted in FIG. 1. In some embodiments, the first lever 102 exerts a first wafer securing force to the semiconductor wafer 104 (e.g., to the edge of the semiconductor wafer 104) in the first lever-closing direction 168 when the first lever 102 is in the first closed position. In some embodiments, the first wafer securing force applied to the semiconductor wafer 104 is a result of the first biasing force applied by the first biasing member 108 to the first lever 102.

In some embodiments, the lever engagement structure 156 comprises a first lever engagement member 120 configured to engage the first lever 102. In some embodiments, the first lever engagement member 120 is configured to exert a first lever-opening force to the first lever 102 to move the first lever 102 from the first closed position to the first open position relative to the platen 114. In some embodiments, the first lever engagement member 120 is coupled to the first power region 165 of the first lever 102. In some embodiments, the first lever engagement member 120 exerts the first lever-opening force to the first power region 165 of the first lever 102 to rotate the first lever 102 in a first lever-opening direction 160 about the axis 166 through the first fulcrum region 164. In some embodiments, the first lever-opening direction 160 is opposite the first lever-closing direction 168. In some embodiments, the first lever 102 moves from the first closed position (such as shown in FIG. 1) to the first open position (such as shown in FIG. 2C) when the first lever-opening force applied by the first lever engagement member 120 overcomes the first biasing force applied by the first biasing member 108.

In some embodiments, when the first lever 102 is in the first open position, the first lever 102 does not obstruct the first path of motion 158 of the semiconductor wafer 104. In some embodiments, the first protrusion 162a does not overlie the semiconductor wafer 104 when the first lever 102 is in the first open position. In some embodiments, when the first lever 102 is in the first open position, the first lever 102 is not in contact with the semiconductor wafer 104. In some embodiments, when the first lever 102 is in the first open position, at least one of the first lever 102 or one or more other levers of the wafer retaining device 100 do not exert a wafer securing force to the semiconductor wafer 104. In some embodiments, the first lever 102 does not exert the first wafer securing force to the semiconductor wafer 104 in the first lever-closing direction 168 when the first lever 102 is in the first open position.

In some embodiments, the second retainer assembly 154, such as a second clamping unit, comprises at least one of a second lever 110, a second mounting member 112 (shown with a dashed-line outline in FIG. 1), a second biasing member 142, or one or more other suitable components. In some embodiments, the second mounting member 112 is coupled to the platen 114. In some embodiments, when the second mounting member 112 is coupled to the platen 114, the second mounting member 112 has a fixed position relative to the platen 114. In some embodiments, the second lever 110 is coupled to, such as pivotally coupled to, the second mounting member 112. In some embodiments, the second biasing member 142 comprises at least one of a first end 142a coupled to the second lever 110 or a second end 142b coupled to the second mounting member 112. In some embodiments, the second biasing member 142 comprises at least one of a second spring, a second solenoid (not shown), or other suitable biasing device. In some embodiments, the second lever 110 comprises at least one of a second weight region 172, a second fulcrum region 174, or a second power region 175. In some embodiments, the second fulcrum region 174 is pivotally coupled to the second mounting member 112.

In some embodiments, the second biasing member 142 is configured to bias the second lever 110 to a second closed position relative to the platen 114. FIG. 1 depicts the second lever 110 in the second closed position in accordance with some embodiments. In some embodiments, the second lever 110 transitions between the second closed position and a second open position relative to the platen 114. FIG. 2C depicts the second lever 110 in the second open position in accordance with some embodiments. In some embodiments, the second biasing member 142 is configured to exert a second biasing force to the second lever 110. In some embodiments, the first end 142a of the second biasing member 142 is coupled to the second power region 175 of the second lever 110. In some embodiments, the second biasing member 142 exerts the second biasing force to the second power region 175 of the second lever 110 to rotate the second lever 110 in a second lever-closing direction 178 about an axis 176 through the second fulcrum region 174. In some embodiments, the axis 176 extends through a location of a second pivot (not shown) pivotally coupling the second fulcrum region 174 to the second mounting member 112. In some embodiments, the wafer retaining device 100 comprises a second hard stop object (not shown) configured to inhibit movement of the second lever 110 in the second lever-closing direction 178 past a defined position, such as the second closed position of the second lever 110 or other position of the second lever 110. Thus, in accordance with some embodiments, when the second lever 110 is in the second closed position, the second hard stop object inhibits the second lever 110 from moving (further) in the second lever-closing direction 178 even when the second biasing member 142 exerts the second biasing force to the second power region 175.

In some embodiments, the second spring of the second biasing member 142 is in an uncompressed and/or extended state when the second lever 110 is in the second open position. In some embodiments, the second spring of the second biasing member 142 is in a compressed and/or loaded state when the second lever 110 is in the second open position. Other configurations of the second spring and/or the second biasing member 142 are within the scope of the present disclosure. In some embodiments, the second biasing force is greater when the second lever 110 is in the second open position than when the second lever 110 is in the second closed position.

In some embodiments, when the second lever 110 is in the second closed position, the second lever 110 obstructs the first path of motion 158 of the semiconductor wafer 104. In some embodiments, a second protrusion 172a of the second weight region 172 overlies the semiconductor wafer 104 when the second lever 110 is in the second closed position. In some embodiments, when the second lever 110 is in the second closed position, the second lever 110 is in at least one of direct contact or indirect contact with the semiconductor wafer 104. In some embodiments, the second lever 110 is in at least one of direct contact or indirect contact with the first surface 104a of the semiconductor wafer 104 when the second lever 110 is in the second closed position. In some embodiments, the second lever 110 is in at least one of direct contact or indirect contact with the edge of the semiconductor wafer 104 when the second lever 110 is in the second closed position. In some embodiments, when the second lever 110 is in the second closed position, at least one of the second lever 110 or one or more other levers of the wafer retaining device 100 exert a wafer securing force to the semiconductor wafer 104 to secure the semiconductor wafer 104 in the target wafer position. In some embodiments, the second lever 110 exerts a second wafer securing force to the semiconductor wafer 104 (e.g., to the edge of the semiconductor wafer 104) in the second lever-closing direction 178 when the second lever 110 is in the second closed position. In some embodiments, the second wafer securing force applied to the semiconductor wafer 104 is a result of the second biasing force applied by the second biasing member 142 to the second lever 110.

In some embodiments, the lever engagement structure 156 comprises a second lever engagement member 122 configured to engage the second lever 110. In some embodiments, the second lever engagement member 122 is configured to exert a second lever-opening force to the second lever 110 to move the second lever 110 from the second closed position to the second open position relative to the platen 114. In some embodiments, the second lever engagement member 122 is coupled to the second power region 175 of the second lever 110. In some embodiments, the second lever engagement member 122 exerts the second lever-opening force to the second power region 175 of the second lever 110 to rotate the second lever 110 in a second lever-opening direction 170 about the axis 176 through the second fulcrum region 174. In some embodiments, the second lever-opening direction 170 is opposite the second lever-closing direction 178. In some embodiments, the second lever 110 moves from the second closed position (such as shown in FIG. 1) to the second open position (such as shown in FIG. 2C) when the second lever-opening force applied by the second lever engagement member 122 overcomes the second biasing force applied by the second biasing member 142.

In some embodiments, when the second lever 110 is in the second open position, the second lever 110 does not obstruct the first path of motion 158 of the semiconductor wafer 104. In some embodiments, the second protrusion 172a does not overlie the semiconductor wafer 104 when the second lever 110 is in the second open position. In some embodiments, when the second lever 110 is in the second open position, the second lever 110 is not in contact with the semiconductor wafer 104. In some embodiments, the second lever 110 does not exert the second wafer securing force to the semiconductor wafer 104 in the second lever-closing direction 178 when the second lever 110 is in the second open position.

In some embodiments, the wafer retaining device 100 comprises any quantity of retainer assemblies, such as one retainer assembly (e.g., the first retainer assembly 152), two retainer assemblies (e.g., the first retainer assembly 152 and the second retainer assembly 154), three retainer assemblies, four retainer assemblies, or more than four retainer assemblies. In some embodiments, each retainer assembly of some or all retainer assemblies of the wafer retaining device 100 comprises at least some of the elements (e.g., a lever, a mounting member and/or a biasing member), configurations, etc. provided herein with respect to the first retainer assembly 152 and/or the second retainer assembly 154 and relationships between the same. In some embodiments, retainer assemblies of the wafer retaining device 100 are configured to be concurrently operated by the lever engagement structure 156.

In some embodiments, the lever engagement structure 156 comprises a body 124. In some embodiments, at least one of the first lever engagement member 120 or the second lever engagement member 122 protrudes from the body 124 of the lever engagement structure 156. In some embodiments, at least one of the first lever engagement member 120 or the second lever engagement member 122 is attached to the body 124. It will be appreciated that, as used herein, by being attached, the first lever engagement member 120, the second lever engagement member 122, and the body 124 are not limited to comprising three separate structures that are attached. Rather, in some embodiments, at least two of the first lever engagement member 120, the body 124, or the second lever engagement member 122 are integrally formed, one piece formed, a single composite piece, etc. In some embodiments, the lever engagement structure 156 comprises two or three or more separate structures that are attached, such as with mechanical fasteners, welding, adhesives, etc.

In some embodiments, the lever engagement structure 156 is configured to engage some or all levers of the wafer retaining device 100 concurrently. In some embodiments, the lever engagement structure 156 comprises any quantity of lever engagement members, such as one lever engagement member (e.g., the first lever engagement member 120), two lever engagement members (e.g., the first lever engagement member 120 and the second lever engagement member 122), three lever engagement members, four lever engagement members or more than four lever engagement members. In some embodiments, the quantity of lever engagement members of the lever engagement structure 156 matches the quantity of retainer assemblies of the wafer retaining device 100. In some embodiments, for each retainer assembly of the wafer retaining device 100, the lever engagement structure 156 comprises a lever engagement member configured to engage a lever of the retainer assembly. In some embodiments, each lever engagement member of one, some or all lever engagement members of the lever engagement structure 156 comprises a (adaptor) pin. In some embodiments, at least one of the first lever engagement member 120 comprises a first (adaptor) pin or the second lever engagement member 122 comprises a second (adaptor) pin. In some embodiments, each retainer assembly of one, some or all retainer assemblies of the wafer retaining device 100 comprises a (side clamp) chuck pin. In some embodiments, at least one of the first lever 102 comprises a first (side clamp) chuck pin or the second lever 110 comprises a second (side clamp) chuck pin.

In some embodiments, the wafer retaining device 100 transitions between an open state and a closed state. FIG. 1 depicts the wafer retaining device 100 in the closed state in accordance with some embodiments. FIG. 2C depicts the wafer retaining device 100 in the open state in accordance with some embodiments. In some embodiments, when the wafer retaining device 100 is in the open state, one, some or all levers of the wafer retaining device 100 are in respective open positions relative to the platen 114. For example, when the wafer retaining device 100 is in the open state, at least one of the first lever 102 is in the first open position, the second lever 110 is in the second open position, or one or more other levers of the wafer retaining device 100 are in respective open positions. In some embodiments, when the wafer retaining device 100 is in the open state, the first path of motion 158 of the semiconductor wafer 104 is not obstructed by one, some or all levers of the wafer retaining device 100.

In some embodiments, when the wafer retaining device 100 is in the closed state, one, some or all levers of the wafer retaining device 100 are in respective open positions relative to the platen 114. In some embodiments, when the wafer retaining device 100 is in the closed state, one, some or all levers of the wafer retaining device 100 are in respective closed positions relative to the platen 114. For example, when the wafer retaining device 100 is in the closed state, at least one of the first lever 102 is in the first closed position, the second lever 110 is in the second closed position, or one or more other levers of the wafer retaining device 100 are in respective closed positions. In some embodiments, when the wafer retaining device 100 is in the closed state, the first path of motion 158 of the semiconductor wafer 104 is obstructed by one, some or all levers of the wafer retaining device 100. In some embodiments, when the wafer retaining device 100 is in the closed state, one, some or all levers of the wafer retaining device 100 exert a wafer securing force to the semiconductor wafer 104, such as at least one of the first wafer securing force applied by the first lever 102, the second wafer securing force applied by the second lever 110, or one or more other wafer securing forces applied by one or more other levers of the wafer retaining device 100, so as to secure the semiconductor wafer 104 in the target wafer position relative to the platen 114.

In some embodiments, prior to the semiconductor wafer 104 being retained by the wafer retaining device 100, the wafer retaining device 100 transitions from the closed state to the open state to receive the semiconductor wafer 104. In some embodiments, upon transitioning to the open state, the wafer retaining device 100 stays in the open state for a duration of time while the semiconductor wafer 104 is moved to the target wafer position relative to the platen 114. In some embodiments, the semiconductor wafer 104 is moved to the target wafer position, such as placed upon the surface 114a of the platen 114, using at least one of a robotic arm, a transfer component, or other suitable component. In some embodiments, in response to the semiconductor wafer 104 being moved to the target wafer position (e.g., in response to the semiconductor wafer 104 being placed on the surface 114a of the platen 114), the wafer retaining device 100 transitions from the open state to the closed state to retain the semiconductor wafer 104. In some embodiments, upon transitioning to the closed state, the wafer retaining device 100 stays in the closed state for a duration of time to retain the semiconductor wafer 104 in the target wafer position relative to the platen 114 while a semiconductor fabrication process is performed on the semiconductor wafer 104. In some embodiments, in response to the semiconductor fabrication process being completed, the wafer retaining device 100 transitions from closed state to open state to release the semiconductor wafer 104. In some embodiments, upon transitioning to the open state, the wafer retaining device 100 stays in the open state for a duration of time to allow the semiconductor wafer 104 to be collected and/or moved from the target wafer position relative to the platen 114 to a location, such as at least one of a wafer storage device, a processing station, etc. In some embodiments, the wafer storage device (not shown) comprises at least one of a front opening unified pod (FOUP), a cassette pod, a reticle pod, or other type of wafer storage device. In some embodiments, the semiconductor wafer 104 is collected and/or moved to the location using at least one of a robotic arm, a transfer component, or other suitable component.

In some embodiments, the wafer retaining device 100 comprises a hard stop device 116 (shown in FIG. 1) configured to separate the semiconductor wafer 104 from a semiconductor processing component by at least a threshold distance. In some embodiments, the hard stop device 116 is coupled, such as detachably mounted, to the platen 114. In some embodiments, the hard stop device 116 has a fixed position relative to the platen 114.

At least one of (i) a dimension d1 (shown in FIG. 1) is between about 15 millimeters to about 25 millimeters, (ii) a dimension d2 is between about 15 millimeters to about 22 millimeters, (iii) a sum of a dimension d3 and a dimension d4 is between about 150 millimeters to about 235 millimeters, (iv) a dimension d5 is between about 15 millimeters to about 18.5 millimeters, (v) a dimension d6 is between about 18.5 millimeters to about 19.5 millimeters. Other values of the dimension d1, the dimension d2, the sum of the dimension d3 and the dimension d4, the dimension d5, and the dimension d6 are within the scope of the present disclosure. In some embodiments, at least one of the dimension d1, the dimension d2, the dimension d3, the dimension d4, the dimension d5, or the dimension d6 is configured based upon a wafer size of at least one of the semiconductor wafer 104 or one or more other semiconductor wafers that the wafer retaining device 100 is configured to retain. In some embodiments, the dimension d1 corresponds to a length (e.g., a maximum length) of a lever (e.g., at least one of the first lever 102, the second lever 110, etc.) along a z direction (shown in FIG. 1). In some embodiments, the dimension d2 corresponds to a thickness of the platen 114 along the z direction. In some embodiments, the dimension d3 corresponds to a length of the platen 114 in an x direction (shown in FIG. 1). In some embodiments, the x direction corresponds to a radial direction (relative to the platen 114, for example). In some embodiments, the dimension d3 corresponds to a diameter of the platen 114. In some embodiments, the dimension d4 corresponds to a length of the hard stop device 116 along the x direction. In some embodiments, the dimension d5 corresponds to a length of a lever (e.g., at least one of the first lever 102, the second lever 110, etc.) along the x direction. In some embodiments, the dimension d6 corresponds to a length of a mounting member (e.g., at least one of the first mounting member 106, the second mounting member 112, etc.) along the z direction. An angle θ1 between a line 182 extending along a surface 186 of a lever (e.g., at least one of the first lever 102, the second lever 110, etc.) and a line 184 extending along a surface 188 of the lever is between about 15 degrees to about 19 degrees. Other values of the angle 61 are within the scope of the present disclosure. In some embodiments, the line 184 is parallel to the z direction. In some embodiments, the angle θ1 is configured based upon a wafer edge profile of the semiconductor wafer 104.

FIGS. 2A-2E illustrate a scenario 200 associated with using the wafer retaining device 100 to retain the semiconductor wafer 104. FIG. 2A illustrates the wafer retaining device 100 in the closed state, in accordance with some embodiments. In some embodiments, the wafer retaining device 100 overlies a pedestal 208. In some embodiments, the pedestal 208 at least one of has a fixed position or does not move. In some embodiments, the lever engagement structure 156 comprises a supplemental structure between the body 124 and the pedestal 208. In some embodiments, the supplemental structure comprises at least one of a supplemental body 206, a structure 202 coupled to at least one of the supplemental body 206 or the body 124, or a structure 204 coupled to at least one of the supplemental body 206 or the body 124.

FIGS. 2B-2C illustrate transition of the wafer retaining device 100 from the closed state to the open state. In some embodiments, the transition from the closed state to the open state is performed in anticipation of receiving the semiconductor wafer 104. FIG. 2B illustrates the wafer retaining device 100 during transition from the closed state to the open state, in accordance with some embodiments. In some embodiments, at least some of the wafer retaining device 100, including the lever engagement structure 156, is moved in a first direction 230 towards the pedestal 208. FIG. 2B depicts the wafer retaining device 100 when the lever engagement structure 156 reaches the pedestal 208 during the movement in the first direction 230. In some embodiments, the wafer retaining device 100 is moved in the first direction 230 using at least one of a robotic arm, a transfer component, or other suitable component. In some embodiments, once the wafer retaining device 100 reaches the pedestal 208 (such as shown in FIG. 2B) at least some of the wafer retaining device 100 continues to be moved in the first direction 230 relative to the lever engagement structure 156. For example, at least one of the platen 114, retainer assemblies, etc. of the wafer retaining device 100 are moved in the first direction 230 relative to the lever engagement structure 156, wherein the lever engagement structure 156 does not move in the first direction 230 due to the lever engagement structure 156 abutting the pedestal 208. In some embodiments, when the lever engagement structure 156 abuts the pedestal 208, the movement of at least some of the wafer retaining device 100 in the first direction 230 causes an opposing force to be applied by the pedestal 208 through the lever engagement structure 156 to one, some or all levers of the wafer retaining device 100. In some embodiments, the opposing force is applied to the lever engagement structure 156 in a second direction 232. In some embodiments, the second direction 232 is opposite the first direction 230. In some embodiments, the opposing force applied to the lever engagement structure 156 translates to lever-opening forces applied by engagement members of the lever engagement structure 156 to one, some or all levers of the wafer retaining device 100, such as at least one of the first lever-opening force applied through the first lever engagement member 120 to the first power region 165 of the first lever 102 to move the first lever 102 in the first lever-opening direction 160, the second lever-opening force applied through the second lever engagement member 122 to the second power region 175 of the second lever 110 to move the second lever 110 in the second lever-opening direction 170, etc. Thus, in accordance with some embodiments, the wafer retaining device 100 transitions from the closed state to the open state by way of the lever engagement structure 156 concurrently moving one, some or all levers of the wafer retaining device 100 in respective lever-opening directions from respective closed positions of the levers to respective open positions of the levers. In some embodiments, the levers transition from the respective closed positions to the respective open positions to transition the wafer retaining device 100 to the open state when respective lever-opening forces applied by the lever engagement structure 156 to levers of the wafer retaining device 100 overcome respective biasing forces applied by respective biasing members of the wafer retaining device 100, such as when at least one of the first lever-opening force overcomes the first biasing force, the second lever-opening force overcomes the second biasing force, or one or more other lever-opening forces exerted through the lever engagement structure 156 overcome one or more other biasing forces. FIG. 2C illustrates the wafer retaining device 100 in the open state, in accordance with some embodiments. In some embodiments, in the open state, at least one of the first power region 165 of the first lever 102, the second power region 175 of the second lever 110, the first lever engagement member 120, or the second lever engagement member 122 extend into one or more openings defined by the platen 114, such as at least one of a groove, a slot, a crevice, etc.

FIG. 2D illustrates transfer of the semiconductor wafer 104 to the target wafer position relative to the platen 114, in accordance with some embodiments. In some embodiments, when the semiconductor wafer 104 is in the target wafer position, a second surface 104b of the semiconductor wafer 104 is in at least one of direct contact or indirect contact with the surface 114a of the platen 114. In some embodiments, the semiconductor wafer 104 is transferred to the target wafer position via a second path of motion 234. In some embodiments, the second path of motion 234 at least one of overlaps with the first path of motion 158 or has a direction opposite to a direction of the first path of motion 158.

FIG. 2E illustrates transition of the wafer retaining device 100 from the open state to the closed state. In some embodiments, the transition from the open state to the closed state to the open state is performed to retain the semiconductor wafer 104 in the target wafer position. In some embodiments, the wafer retaining device 100 is in the closed state while a semiconductor fabrication process is performed on the semiconductor wafer 104 to retain the semiconductor wafer 104 in the target wafer position relative to the platen 114 while the semiconductor fabrication process is performed.

In some embodiments, at least some of the wafer retaining device 100, including the lever engagement structure 156, is moved in the second direction 232 away from the pedestal 208. In some embodiments, the wafer retaining device 100 is moved in the second direction 232 using at least one of a robotic arm, a transfer component, or other suitable component. In some embodiments, during movement of the wafer retaining device 100 in the second direction 232, at least some the opposing force applied by the pedestal 208 through the lever engagement structure 156 is released such that biasing forces exerted by one, some or all biasing members of the wafer retaining device 100 to move one, some or all levers of the wafer retaining device 100 in one or more respective lever-closing directions to transition from one or more respective open positions to one or more respective closed positons. For example, during movement of the wafer retaining device 100 in the second direction 232, at least one of the first biasing force applied by the first biasing member 108 moves the first lever 102 in the first lever-closing direction 168, the second biasing force applied by the second biasing member 142 moves the second lever 110 in the second lever-closing direction 178, etc. Thus, in accordance with some embodiments, the wafer retaining device 100 transitions from the open state to the closed state by way of the biasing members of the wafer retaining device 100 concurrently moving one, some or all levers of the wafer retaining device 100 in respective lever-closing directions from respective open positions of the levers to respective closed positions of the levers.

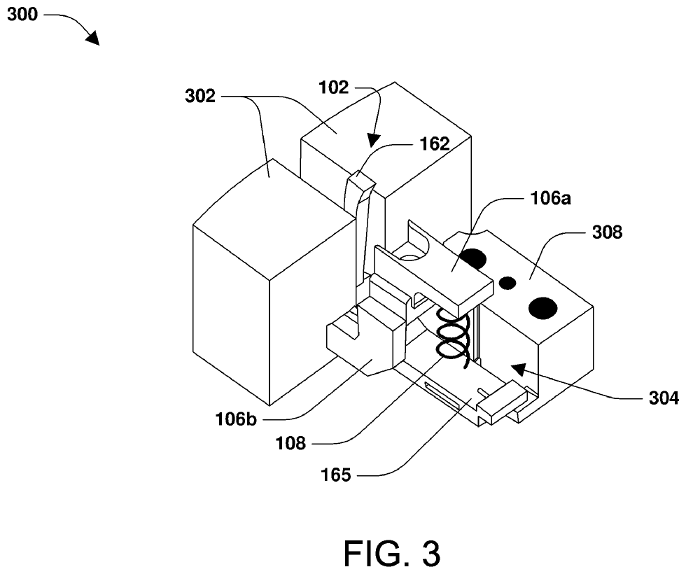

FIG. 3 illustrates a perspective view of a portion 300 of the wafer retaining device 100, in accordance with some embodiments. In some embodiments, the wafer retaining device 100 comprises a first protective structure 302 at least partially surrounding the first lever 102. In some embodiments, the first protective structure 302 protects at least one of the first lever 102 or one or more other components of the first retainer assembly 152 from at least one of debris, damage from a collision with an object, etc. In some embodiments, the first protective structure 302 at least partially surrounds at least one of the first fulcrum region 164 of the first lever 102 or the first pivot coupling the first fulcrum region 164 to the first mounting member 106. In some embodiments, the first protective structure 302 is coupled to at least one of the first mounting member 106 or the platen 114.

In some embodiments, the first mounting member 106 comprises at least one of a first portion 106a or a second portion 106b. In some embodiments, the first portion 106a is attached to the second portion 106b. It will be appreciated that, as used herein, by being attached, the first portion 106a and the second portion 106b are not limited to comprising two separate structures that are attached. Rather, in some embodiments, the first portion 106a and the second portion 106b are integrally formed, one piece formed, a single composite piece, etc. In some embodiments, the first mounting member 106 comprises two or three or more separate structures that are attached, such as with mechanical fasteners, welding, adhesives, etc.

In some embodiments, the second end 108b of the first biasing member 108 is coupled to the first portion 106a of the first mounting member 106. In some embodiments, at least one of the first portion 106a or the second portion 106b of the first mounting member 106 is coupled to the platen 114 such that the first mounting member 106 has a fixed position relative to the platen 114. In some embodiments, at least one of the first portion 106a or the second portion 106b of the first mounting member 106 is coupled to a portion 308 of the platen 114. In some embodiments, the platen 114 defines an opening 304 between the portion 308 and a second portion (not shown) of the platen 114. In some embodiments, the opening 304 allows the first power region 165 of the first lever 102 to move (in the first lever-opening direction 160, for example) through the opening 304 from the first closed position to the first open position when the wafer retaining device 100 transitions from the closed state to the open state.

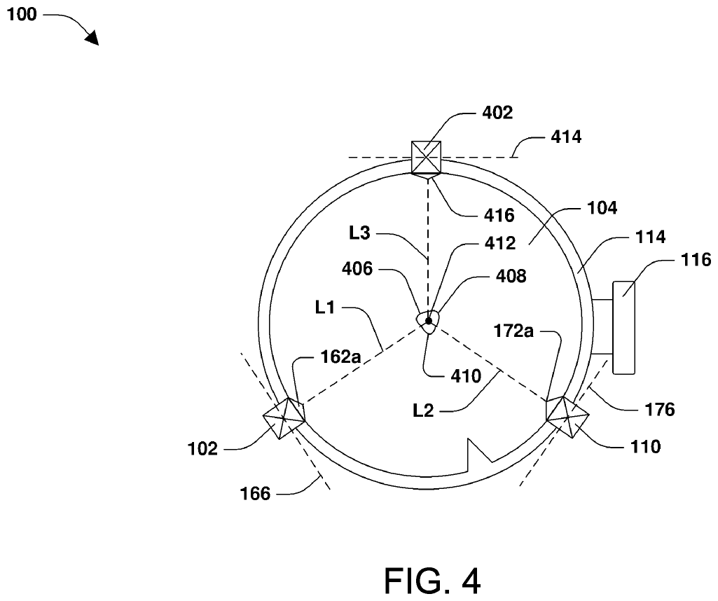

FIG. 4 illustrates a top view of the wafer retaining device 100 when the semiconductor wafer 104 is retained by the wafer retaining device 100, in accordance with some embodiments. FIG. 4 depicts the wafer retaining device 100 in the closed state in accordance with some embodiments. In some embodiments, the wafer retaining device 100 comprises the first retainer assembly 152 comprising the first lever 102, the second retainer assembly 154 comprising the second lever 110, and a third retainer assembly comprising a third lever 402. The view depicted in FIG. 4 shows top surfaces of respective weight regions of the first lever 102, the second lever 110, and the third lever 402.

In some embodiments, the third retainer assembly comprises at least some of the elements, configurations, etc., provided herein with respect to the first retainer assembly 152 and/or the second retainer assembly 154 and relationships between the same. In some embodiments, the third retainer assembly comprises at least one of a third mounting member (not shown), a third biasing member (not shown), or one or more other suitable components.

In some embodiments, the third mounting member is coupled to the platen 114. In some embodiments, when the third mounting member is coupled to the platen 114, the third mounting member has a fixed position relative to the platen 114. In some embodiments, the third biasing member comprises at least one of a first end coupled to the third lever 402 or a second end coupled to the third mounting member. In some embodiments, the third biasing member comprises at least one of a third spring, a third solenoid (not shown), or other suitable biasing device. In some embodiments, the third lever 402 comprises at least one of a third weight region, a third fulcrum region, or a third power region. In some embodiments, the third fulcrum region is pivotally coupled to the third mounting member. In some embodiments, the third biasing member is configured to bias the third lever 402 to a third closed position relative to the platen 114. In some embodiments, the third lever 402 transitions between the third closed position and a third open position relative to the platen 114. In some embodiments, the third biasing member is configured to exert a third biasing force to the third lever 402 (when the third lever 402 is in the third closed position, for example). In some embodiments, the first end of the third biasing member is coupled to the third power region of the third lever 402. In some embodiments, the third biasing member exerts the third biasing force to the third power region of the third lever 402 to rotate the third lever 402 in a third lever-closing direction about an axis 414 through the third fulcrum region. In some embodiments, the axis 414 extends through a location of a third pivot (not shown) pivotally coupling the third fulcrum region to the third mounting member. Representations of the axis 166 associated with the first lever 102 and the axis 176 associated with the second lever 110 are depicted in FIG. 4 in accordance with some embodiments. In some embodiments, the wafer retaining device 100 comprises a third hard stop object (not shown) configured to inhibit movement of the third lever 402 in the third lever-closing direction past a defined position, such as the third closed position of the third lever 402 or other position of the third lever 402.

In some embodiments, the third spring of the third biasing member is in an uncompressed and/or extended state when the third lever 402 is in the third open position. In some embodiments, the third spring of the third biasing member is in a compressed and/or loaded state when the third lever 402 is in the third open position. Other configurations of the third spring and/or the third biasing member are within the scope of the present disclosure. In some embodiments, the third biasing force is greater when the third lever 402 is in the third open position than when the third lever 402 is in the third closed position.

In some embodiments, when the third lever 402 is in the third closed position, the third lever 402 obstructs the first path of motion 158 (shown in FIG. 1) of the semiconductor wafer 104. In some embodiments, a third protrusion 416 of the third weight region of the third lever 402 overlies the semiconductor wafer 104 when the third lever 402 is in the third closed position. In some embodiments, when the third lever 402 is in the third closed position, the third lever 402 is in at least one of direct contact or indirect contact with the semiconductor wafer 104. In some embodiments, the third lever 402 is in at least one of direct contact or indirect contact with the first surface 104a of the semiconductor wafer 104 when the third lever 402 is in the third closed position. In some embodiments, the third lever 402 is in at least one of direct contact or indirect contact with the edge of the semiconductor wafer 104 when the third lever 402 is in the third closed position. In some embodiments, when the third lever 402 is in the third closed position, at least one of the third lever 402 or one or more other levers of the wafer retaining device 100 exert a wafer securing force to the semiconductor wafer 104 to secure the semiconductor wafer 104 in the target wafer position. In some embodiments, the third lever 402 exerts a third wafer securing force to the semiconductor wafer 104 (e.g., to the edge of the semiconductor wafer 104) in the third lever-closing direction when the third lever 402 is in the third closed position. In some embodiments, the third wafer securing force applied to the semiconductor wafer 104 is a result of the third biasing force applied by the third biasing member to the third lever 402.

In some embodiments, the lever engagement structure 156 comprises a third lever engagement member (not shown) configured to engage the third lever 402. In some embodiments, the third lever engagement member is configured to exert a third lever-opening force to the third lever 402 to move the third lever 402 from the third closed position to the third open position relative to the platen 114. In some embodiments, the third lever engagement member is coupled to the third power region of the third lever 402. In some embodiments, the third lever engagement member exerts the third lever-opening force to the third power region of the third lever 402 to rotate the third lever 402 in a third lever-opening direction about the axis 414. In some embodiments, the third lever-opening direction is opposite the third lever-closing direction. In some embodiments, the third lever 402 moves from the third closed position to the third open position when the third lever-opening force applied by the third lever engagement member overcomes the third biasing force applied by the third biasing member.

In some embodiments, when the third lever 402 is in the third open position, the third lever 402 does not obstruct the first path of motion 158 of the semiconductor wafer 104. In some embodiments, the third protrusion 416 does not overlie the semiconductor wafer 104 when the third lever 402 is in the third open position. In some embodiments, when the third lever 402 is in the third open position, the third lever 402 is not in contact with the semiconductor wafer 104. In some embodiments, the third lever 402 does not exert the third wafer securing force to the semiconductor wafer 104 in the third lever-closing direction when the third lever 402 is in the third open position.

FIG. 4 depicts line L1 extending from the first lever 102 to a point 412, line L2 extending from the second lever 110 to the point 412, and line L3 extending from the third lever 402 to the point 412. In some embodiments, the point 412 corresponds to a center of at least one of the platen 114 or the semiconductor wafer 104. In some embodiments, levers of the wafer retaining device 100 are spaced about evenly apart about the platen 114 such that angles 406, 408, and 410 are about equal to each other. The angle 410 between the line L1 and the line L2 is between about 110 degrees to about 130 degrees. The angle 406 between the line L1 and the line L3 is between about 110 degrees to about 130 degrees. The angle 408 between the line L2 and the line L3 is between about 110 degrees to about 130 degrees. Other values of angles 406, 408, and 410 are within the scope of the present disclosure.

Embodiments are contemplated in which one, some or all protrusions of respective levers, such as at least one of the first protrusion 162a, the second protrusion 172a, or the third protrusion 416, do not overlie the semiconductor wafer 104 when the respective levers are in respective closed positions. Embodiments are contemplated in which at least one of the first lever 102 does not comprise the first protrusion 162a, the second lever 110 does not comprise the second protrusion 172a, the third lever 402 does not comprise the third protrusion 416, etc.

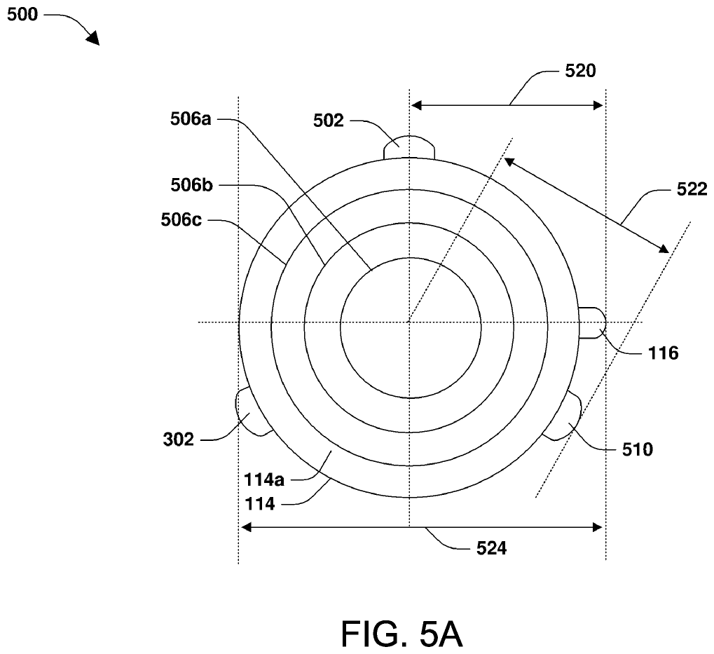

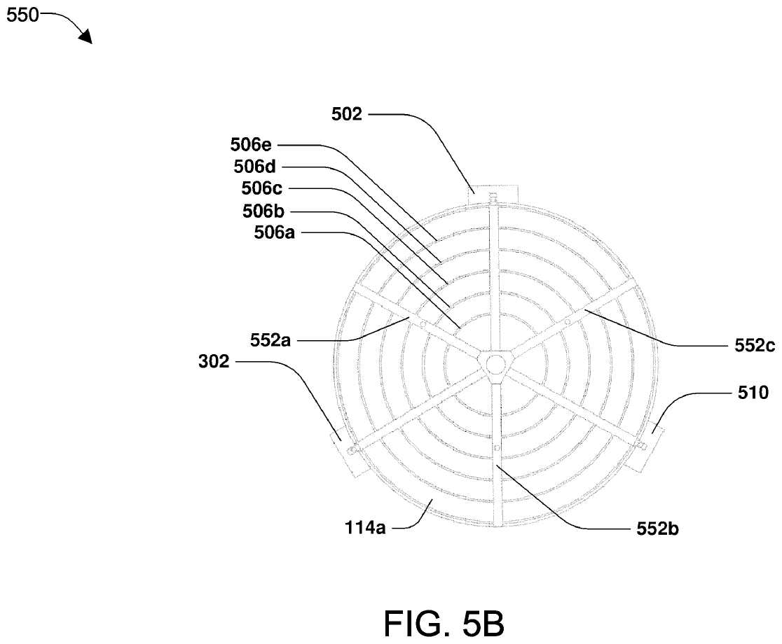

FIG. 5A illustrates a first top-view representation 500 of the wafer retaining device 100 without a semiconductor wafer disposed thereon, in accordance with some embodiments. FIG. 5A shows top surfaces of protective structures disposed over the first lever 102, the second lever 110, and the third lever 402, respectively. In some embodiments, the wafer retaining device 100 comprises at least one of the first protective structure 302 at least partially surrounding the first lever 102, a second protective structure 510 at least partially surrounding the second lever 110, or a third protective structure 502 at least partially surrounding the third lever 402. FIG. 5A shows the surface 114a of the platen 114 in accordance with some embodiments. In some embodiments, the platen 114 comprises one or more annular grooves defined in the surface 114a for heat dissipation. In some embodiments, the one or more annular grooves comprise at least one of annular groove 506a, annular groove 506b, annular groove 506c, or one or more other annular grooves. A dimension 520 is at most about 120 millimeters. A dimension 522 is at most about 115 millimeters. A dimension 524 is between about 150 millimeters to about 235 millimeters. Other values of the dimension 520, the dimension 522, and the dimension 524 are within the scope of the present disclosure. In some embodiments, at least one of the dimension 520, the dimension 522, or the dimension 524 is configured based upon a wafer size of at least one of the semiconductor wafer 104 or one or more other semiconductor wafers that the wafer retaining device 100 is configured to retain.

FIG. 5B illustrates a second top-view representation 550 of the wafer retaining device 100 without a semiconductor wafer disposed thereon, in accordance with some embodiments. In some embodiments, the wafer retaining device 100 comprises at least one of the first protective structure 302, the second protective structure 510, or the third protective structure 502. FIG. 5B shows the surface 114a of the platen 114 in accordance with some embodiments. In some embodiments, the one or more annular grooves defined in the surface 114a comprise at least one of annular groove 506a, annular groove 506b, annular groove 506c, annular groove 506d, annular groove 506e, or one or more other annular grooves. In some embodiments, the platen 114 comprises one or more first radial grooves defined in the surface 114a. In some embodiments, the one or more first radial grooves comprise at least one of a radial groove 552a, a radial groove 552b, a radial groove 552c, or one or more other radial grooves. In some embodiments, the one or more first radial grooves are adapted to receive a lifter.

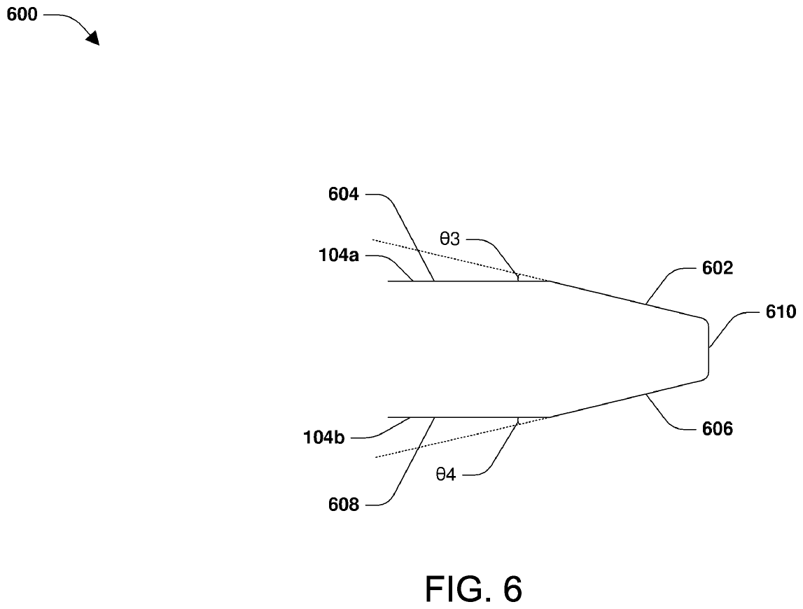

FIG. 6 illustrates a cross-sectional view of a portion 600 of the semiconductor wafer 104 comprising the edge (shown with reference number 610) of the semiconductor wafer 104 in accordance with some embodiments. In some embodiments, a first portion 602 of the first surface 104a is tapered at an angle θ3 relative to a second portion 604 of the first surface 104a. The angle θ3 is between about 15 degrees to about 40 degrees. Other values of the angle θ3 are within the scope of the present disclosure. In some embodiments, a first portion 606 of the second surface 104b is tapered at an angle θ4 relative to a second portion 608 of the second surface 104b. The angle θ4 is between about 15 degrees to about 40 degrees. Other values of the angle θ4 are within the scope of the present disclosure. In some embodiments, the angle θ1 (shown in FIG. 1) is configured based upon at least one of the angle θ3 or the angle θ4 of the semiconductor wafer 104.

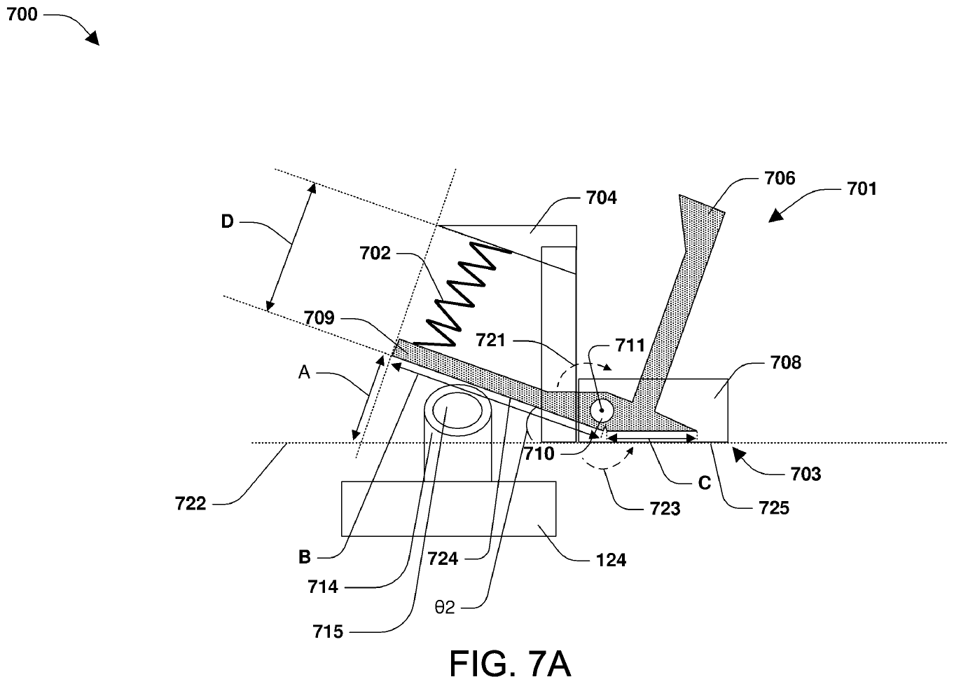

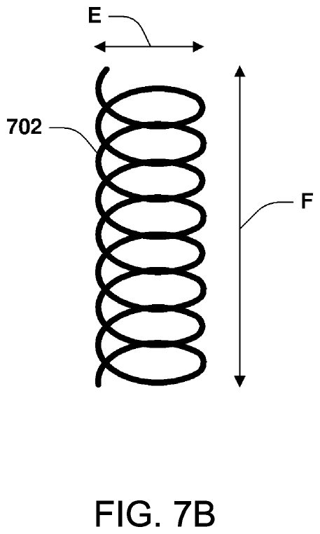

FIG. 7A illustrates a retainer assembly 700 of the wafer retaining device 100, in accordance with some embodiments. In some embodiments, the retainer assembly 700 corresponds to at least one of the first retainer assembly 152, the second retainer assembly 154, or the third retainer assembly. In some embodiments, the retainer assembly 700 comprises at least one of a lever 701, a mounting member 703, or a biasing member 702, such as at least one of a spring, a solenoid (not shown), or other suitable biasing device. In some embodiments, the lever 701 corresponds to at least one of the first lever 102, the second lever 110, or the third lever 402. In some embodiments, the lever 701 comprises a side clamp chuck pin. In some embodiments, the mounting member 703 corresponds to at least one of the first mounting member 106, the second mounting member 112, or the third mounting member. In some embodiments, the mounting member 703 comprises a first portion 704 and a second portion 708. In some embodiments, the biasing member 702 corresponds to at least one of the first biasing member 108, the second biasing member 142, or the third biasing member.

FIG. 7A depicts the lever 701 in an open position, in accordance with some embodiments. In some embodiments, the lever 701 comprises at least one of a weight region 706, a fulcrum region 710, or a power region 709. In some embodiments, the lever 701 comprises at least one of one or more metals, one or more polymer-based materials, or one or more other suitable materials. In some embodiments, a first portion of the lever 701 comprises one or more first materials and a second portion of the lever 701 comprises one or more second materials. In some embodiments, the first portion of the lever 701 comprises at least one of the weight region 706 or the power region 709. In some embodiments, the one or more first materials comprise one or more metals, such as at least one of an aluminum alloy or one or more other suitable materials. In some embodiments, the second portion of the lever 701 comprises the fulcrum region. In some embodiments, the one or more second materials comprise one or more polymer-based materials, such as at least one of polyimide, Vespel®, or one or more other suitable polymer-based materials.

In some embodiments, the power region 709 is in contact with a lever engagement member 714 coupled to the body 124 of the lever engagement structure 156. In some embodiments, the lever engagement member 714 corresponds to at least one of the first lever engagement member 120, the second lever engagement member 122, or the third lever engagement member. In some embodiments, a bearing 715 of the lever engagement member 714 is in at least one of direct contact or indirect contact with the power region 709 of the lever 701. In some embodiments, the fulcrum region 710 is pivotally coupled to the second portion 708 of the mounting member 703 such that the lever 701 pivots about an axis 711 through the fulcrum region 710 in a lever-opening direction 721 and a lever-closing direction 723. In some embodiments, the axis 711 extends through a location of a pivot (not shown) pivotally coupling the fulcrum region 710 to the mounting member 703. In some embodiments, the pivot (or other component of the retainer assembly 700) comprises an arresting portion to retain the lever 701 in the open position once the lever 701 (i) moves past a point of no return during movement of the lever 701 in the lever-opening direction 721, or (ii) reaches the open position.

At least one of (i) a dimension A is between about 5 millimeters to about 12 millimeters, (ii) a dimension C is between about 5 millimeters to about 12 millimeters, or (iii) a dimension D is between about 5 millimeters to about 12 millimeters. Other values of the dimension A, the dimension C, and the dimension D are within the scope of the present disclosure. In some embodiments, the dimension D corresponds to a spring length (e.g., a minimum spring length) of the biasing member 702 when the lever 701 is in the open position. In some embodiments, the dimension A is greater than the dimension C. In some embodiments, the dimension D is greater than the dimension A. In some embodiments, a ratio of the dimension A to dimension B is between about 1:1 to about 1:3, such as about 1:2.2. In some embodiments, a ratio of the dimension A to the dimension C is between about 1:1 to about 3:1, such as about 1.8:1. In some embodiments, a ratio of the dimension B to the dimension C is between about 2:1 to about 8:1, such as about 3.9:1. In some embodiments, a ratio A:B:C corresponds to about 1.8:3.9:1. An angle θ2 between a surface 724 of the lever 701 and a line 722 is between about 20 degrees to about 30 degrees. Other values of the angle θ2 are within the scope of the present disclosure. In some embodiments, the line 722 is parallel to at least some of the surface 114a of the platen 114. In some embodiments, the line 722 corresponds to a direction of extension of a surface 725 of the second portion 708 of the mounting member 703.

FIG. 7B illustrates the biasing member 702, in accordance with some embodiments. In some embodiments, the biasing member 702 comprises a spring having a spring diameter E and a spring length F. In some embodiments, the spring comprises one or more metals, such as at least one of steel or one or more other suitable metals. In some embodiments, the spring diameter E and the spring length F correspond to a spring diameter and a spring length, respectively, of the spring in an uncompressed and/or extended state, such as when the lever 701 is in the closed position. The spring diameter E is between about 3 millimeters to about 7 millimeters. The spring length F is between about 18 millimeters to about 22 millimeters. A spring rate K of the spring is at least about 0.08 kilogram-force/millimeter (Kgf/mm). Other values of the spring diameter E, the spring length F, and the spring rate K are within the scope of the present disclosure.

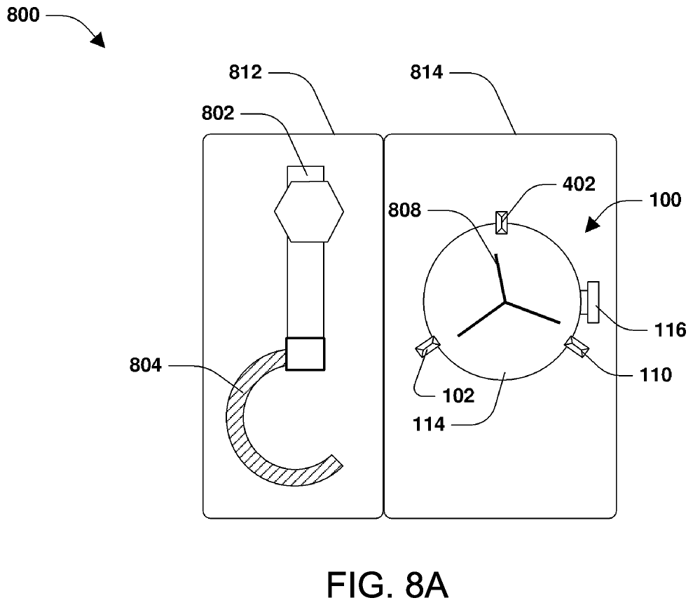

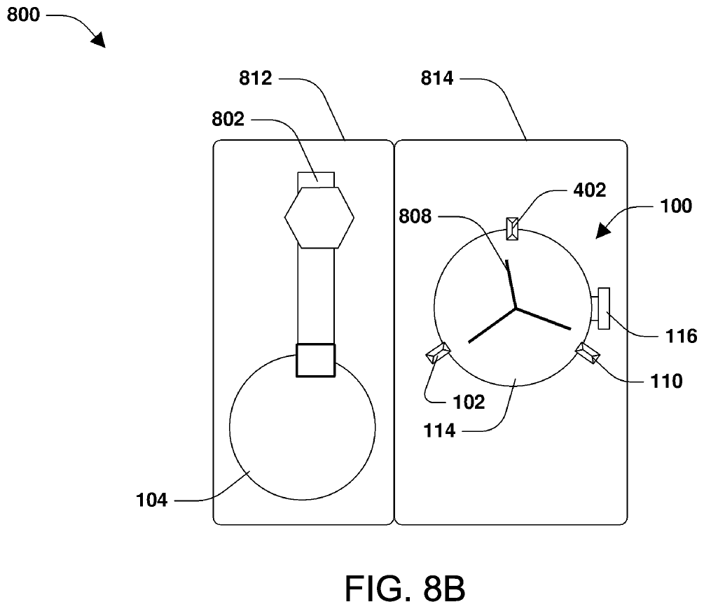

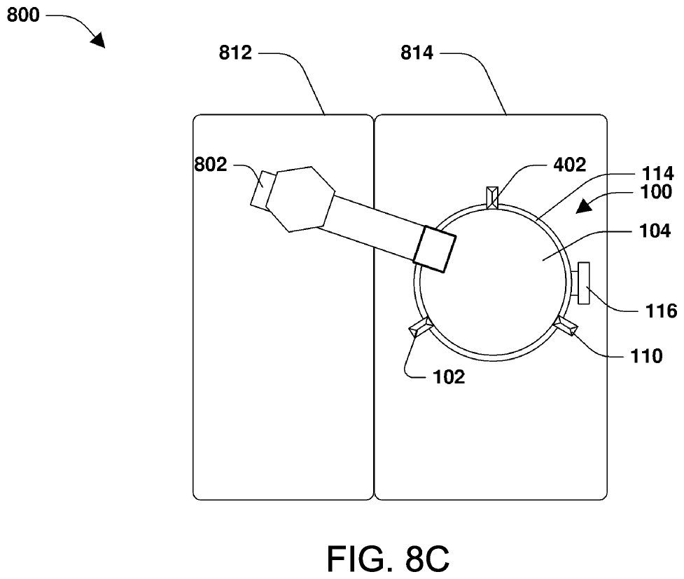

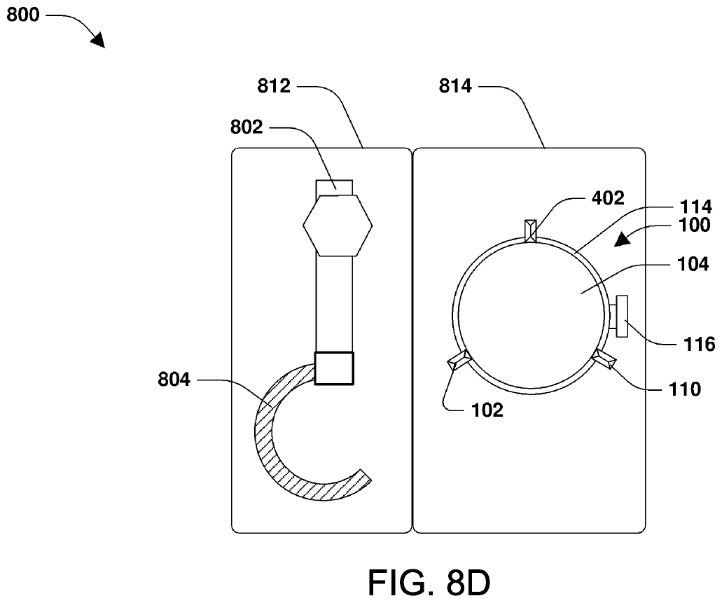

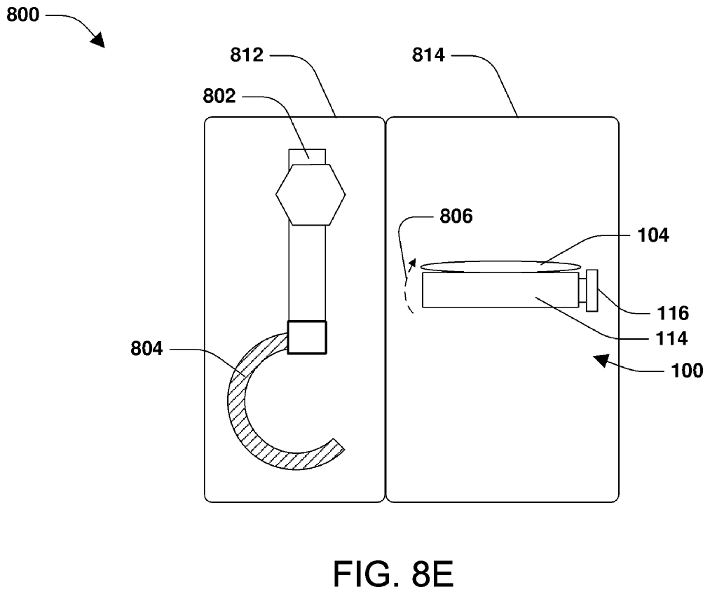

FIGS. 8A-8E illustrate top views of a scenario 800 associated with using the wafer retaining device 100 to retain the semiconductor wafer 104. FIG. 8A illustrates the wafer retaining device 100 in an environment 850 comprising at least one of a handler box 812 or a processing chamber 814, such as a target chamber, in accordance with some embodiments. In some embodiments, at least one of an arm 802 or a wafer holder 804 coupled to the arm 802 is disposed in the handler box 812. In some embodiments, the arm 802 comprises a robotic arm. In some embodiments, the wafer retaining device 100 is disposed in the processing chamber 814. In some embodiments, a lifter 808 is disposed over the platen 114 in the processing chamber 814. In some embodiments, the lifter 808 is used to mount the semiconductor wafer 104 to the target wafer position relative to the platen 114. FIG. 8B illustrates the semiconductor wafer 104 held using the wafer holder 804, in accordance with some embodiments. In some embodiments, the lifter 808 overlies the platen 114. FIG. 8C illustrates transfer of the semiconductor wafer 104 from a first position in the handler box 812 to a second position in the processing chamber 814, in accordance with some embodiments. In some embodiments, when the semiconductor wafer 104 is in the second position (such as shown in FIG. 8C), the semiconductor wafer 104 is disposed on the lifter 808 overlying the platen 114. In some embodiments, the semiconductor wafer 104 is transferred from the first position to the second position using the arm 802. FIG. 8D illustrates transfer of the wafer holder 804 to the handler box 812, in accordance with some embodiments. In some embodiments, in response to or concurrently with transferring the wafer holder 804 to the handler box 812, the lifter 808 moves towards the platen 114 while the semiconductor wafer 104 is mounted on the lifter 808 to move the semiconductor wafer 104 to the target wafer position relative to the platen 114, such as along the second path of motion 234 (shown in FIG. 2D). In some embodiments, the lifter 808 enters one or more radial grooves in the platen 114, such as the one or more first radial grooves (shown in FIG. 5B), to permit the semiconductor wafer 104 to be retained in the target wafer position relative to the wafer retaining device 100. In some embodiments, at least a portion of the lifter 808 is disposed in the one or more radial grooves, such as the one or more first radial grooves, when the semiconductor wafer 104 is in the target wafer position. In some embodiments, prior to moving the semiconductor wafer 104 to the target wafer position relative to the platen 114, the wafer retaining device 100 transitions from the closed state to the open state to receive the semiconductor wafer 104. In some embodiments, in response to moving the semiconductor wafer 104 to the target wafer position relative to the platen 114, the wafer retaining device 100 transitions from the open state to the closed state to retain the semiconductor wafer 104. FIG. 8E illustrates rotation 806 of the semiconductor wafer 104 and the wafer retaining device 100 to a vertical orientation, in accordance with some embodiments. In some embodiments, a semiconductor fabrication process is performed on the semiconductor wafer 104 while the semiconductor wafer 104 and the wafer retaining device 100 are in the vertical orientation shown in FIG. 8E.

In some embodiments, the processing chamber 814 is defined by one or more walls of a processing station configured to perform the semiconductor fabrication process on the semiconductor wafer 104 to produce a processed semiconductor wafer. In some embodiments, the processing station comprises the handler box 812. In some embodiments, the processing station performs the semiconductor fabrication process on the semiconductor wafer 104 while the semiconductor wafer 104 is retained by the wafer retaining device 100 in the processing chamber 814. In some embodiments, the processing station comprises at least one of (i) ion implantation equipment, (ii) chemical vapor deposition (CVD) equipment, (iii) physical vapor deposition (PVD) equipment, (iv) etching equipment, such as at least one of plasma etching equipment, wet etching equipment, dry etching equipment, reactive-ion etching (RIE) equipment, atomic layer etching (ALE) equipment, buffered oxide etching equipment, or ion beam milling equipment, (v) lithography equipment, (vi) chemical mechanical planarization (CMP) equipment, (vii) plating equipment, (viii) cleaning equipment, (ix) a furnace, such as a semiconductor furnace tool, or (x) other equipment. In some embodiments, the semiconductor fabrication process comprises at least one of an ion implantation process, a PVD process, a plating process, an etching process, a lithography process, a CMP process, a CVD process, a thermal process, a cleaning process, or other process.

In some embodiments, responsive to performing the semiconductor fabrication process on the semiconductor wafer 104 to produce the processed semiconductor wafer, the wafer retaining device 100 releases the semiconductor wafer 104 by transitioning from the closed state to the open state, wherein the processed semiconductor wafer is removed from the wafer retaining device 100 while the wafer retaining device 100 is in the open state.

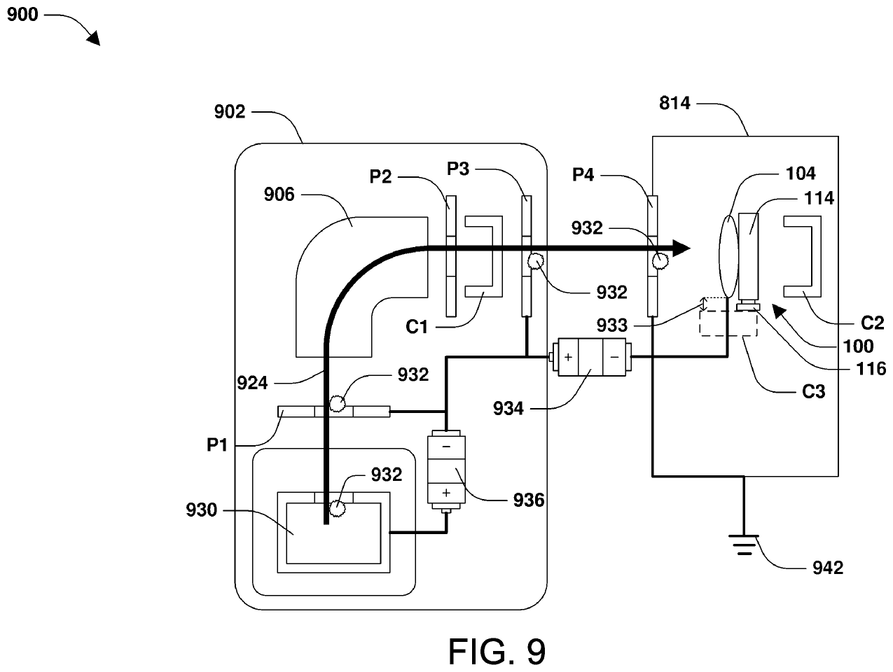

FIG. 9 illustrates a scenario 900 associated with the semiconductor fabrication process performed on the semiconductor wafer 104, in accordance with some embodiments. In some embodiments, the processing chamber 814 comprises an ion implantation chamber and the semiconductor fabrication process comprises an ion implantation process. In some embodiments, the processing station comprises an implanter tool 902 comprising one or more ion implantation components used in the ion implantation process. In some embodiments, the processing station comprises at least one of an ion source component 930, a first plate P1, a beamline chamber 906, a second plate P2, a first faraday cup C1, a fourth plate P4, a second faraday cup C2, a third faraday cup C3, a first power source 936, or a second power source 934.

In some embodiments, ions 932, such as ion plasma, travel along an ion plasma path 924 to treat the semiconductor wafer 104. In some embodiments, at least some of the ions 932 are implanted into the semiconductor wafer 104. In some embodiments, the ions 932 are implanted into the semiconductor wafer 104 to form a doped region of a semiconductor device, such as at least one of a transistor, a diode, etc. In some embodiments, at least one of the first plate P1, the second plate P2, the third plate P3, or the fourth plate P4 define openings for shaping ion plasma traveling along the ion plasma path 924. In some embodiments, at least one of the first plate P1, the second plate P2, the third plate P3, or the fourth plate P4 comprises at least one of graphite or other suitable material. In some embodiments, at least one of a voltage between the first plate P1 and the ion source component 930 or a voltage between the third plate P3 and the semiconductor wafer 104 is controlled to guide a flow direction of the ion plasma. In some embodiments, a quantity of plates of the processing station or a voltage applied by at least one of the first power source 936 or the second power source 934 depends upon one or more parameters of the ion implantation process, such as a target implantation depth of the ion implantation process.

In some embodiments, the first plate P1 serves as a suppressor electrode for suppressing secondary electrons from interacting with ion plasma. In some embodiments, the secondary electrons are produced by collision between ions and at least one of electrons or gas molecules in the processing chamber 814. In some embodiments, a vacuum is established in the processing chamber 814. In some embodiments, an implantation depth of the ion implantation process depends upon an energy level of ion plasma applied to the semiconductor wafer 104, which depends upon the voltage between the third plate P3 and the semiconductor wafer 104. In some embodiments, the voltage is controlled to achieve the target implantation depth, such as by controlling the voltage such that ions implanted into the semiconductor wafer 104 have a depth of about the target implantation depth. The fourth plate P4 is grounded (as shown in the scenario 900 of FIG. 9) or is not grounded.

In some embodiments, a faraday cup of the processing station, such as at least one of the first faraday cup C1, the second faraday cup C2, or the third faraday cup C3, is configured to detect ions during the ion implantation process performed on the semiconductor wafer 104. In some embodiments, the faraday cup measures a quantity of ions impinging upon the faraday cup during the ion implantation process. In some embodiments, the first faraday cup C1 is disposed in a position shown in FIG. 9 during a first part of the ion implantation process. In some embodiments, the first faraday cup C1 is configured to measure a first quantity of ions during the first part of the ion implantation process. In some embodiments, after the first part of the ion implantation process, the first faraday cup C1 is moved to a position away from the ion plasma path 924 to allow ions 932 to pass along the ion plasma path 924 through at least one of the third plate P3 or the fourth plate P4. In some embodiments, one or more parameters of the ion implantation process are at least one of controlled, adjusted, etc. based upon the first quantity of ions.

In some embodiments, the second faraday cup C2 is disposed in a detecting position (not shown) to detect and/or measure ions 932. In some embodiments, the detecting position corresponds to a position of the semiconductor wafer 104 as shown in FIG. 9. In some embodiments, the second faraday cup C2 is disposed in the detecting position before the semiconductor wafer 104 and the wafer retaining device 100 are positioned in respective positions shown in FIG. 9. In some embodiments, when the second faraday cup C2 is disposed in the detecting position, the second faraday cup C2 measures a second quantity of ions of the ion implantation process. In some embodiments, in response to measuring the second quantity of ions, at least one of (i) the second faraday cup C2 is moved to a position of the second faraday cup C2 shown in FIG. 9, or (ii) the semiconductor wafer 104 and the wafer retaining device 100 are positioned in their respective positions shown in FIG. 9. In some embodiments, one or more parameters of the ion implantation process are at least one of controlled, adjusted, etc. based upon the second quantity of ions.

In some embodiments, the third faraday cup C3 is used to at least one of detect ions or determine one or more measures of ions during the ion implantation process, such as while the semiconductor wafer 104 is treated with ion plasma. In some embodiments, the one or more measures comprise a quantity of ions detected by the third faraday cup C3. In some embodiments, the hard stop device 116 is configured to separate the semiconductor wafer 104 from the third faraday cup C3 by at least a threshold distance 933. The threshold distance 933 is between about 100 millimeters to about 300 millimeters. Other values of the threshold distance 933 are within the scope of the present disclosure. In some embodiments, the third faraday cup C3 at least one of coupled to, moved with, or kept proximal to the wafer retaining device 100. In some embodiments, using the hard stop device 116 to establish a separation of at least the threshold distance 933 between the semiconductor wafer 104 and the third faraday cup C3 provides for increased accuracy and/or precision of the one or more measures determined using the third faraday cup C3. In some embodiments, one or more parameters of the ion implantation process are at least one of controlled, adjusted, etc. based upon the one or more measures determined using the third faraday cup C3.

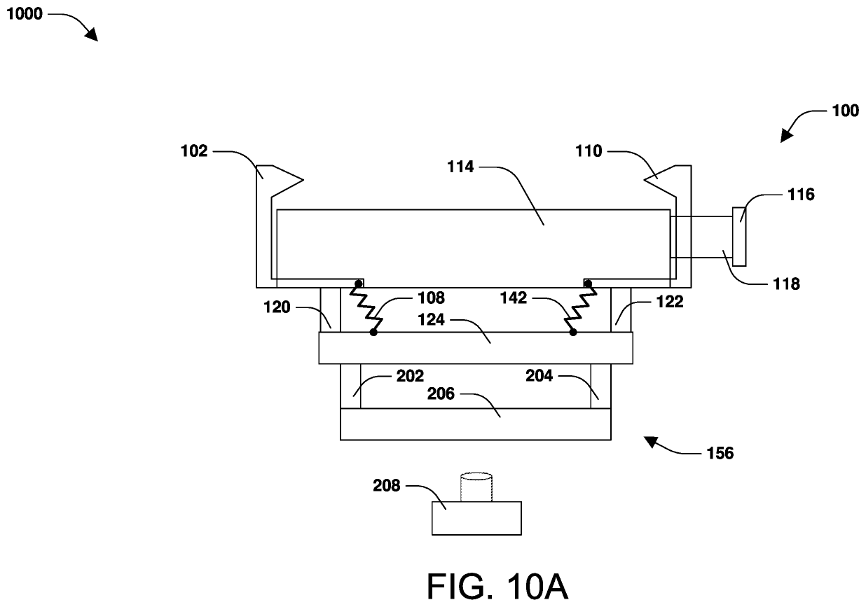

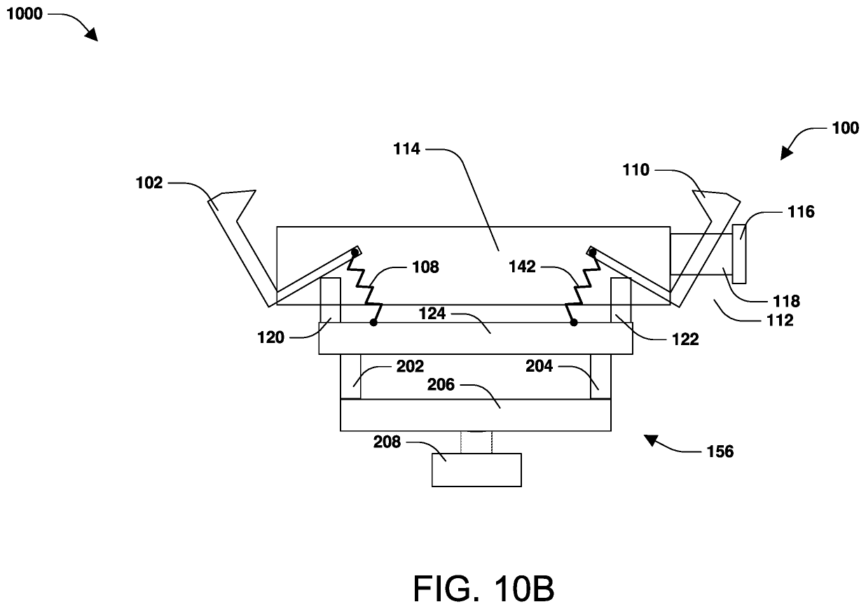

Other configurations of one or more biasing members of the wafer retaining device 100 other than those shown in FIG. 1 and FIGS. 2A-2E are within the scope of the present disclosure. FIGS. 10A-10B illustrate a scenario 1000 associated with the wafer retaining device 100 according to an embodiment in which a spring of a biasing member is (i) in an uncompressed state when a corresponding lever is in a closed position and/or (ii) in an extended state when the corresponding lever is in an open position. FIG. 10A illustrates the wafer retaining device 100 in the closed state, in accordance with some embodiments. In some embodiments, the first spring of the first biasing member 108 is coupled to the first lever 102 and the body 124 of the lever engagement structure 156, such as where one end of the first spring is coupled to the first lever 102 and another end of the first spring is coupled to the body 124. In some embodiments, the second spring of the second biasing member 142 is coupled to the second lever 110 and the body 124 of the lever engagement structure 156, such as where one end of the second spring is coupled to the second lever 110 and another end of the second spring is coupled to the body 124. In some embodiments, when the first lever 102 is in the first closed position, the first spring of the first biasing member 108 is in an uncompressed state. In some embodiments, when the second lever 110 is in the second closed position, the second spring of the second biasing member 142 is in an uncompressed state. When a spring is in an uncompressed state, an un-extended state, an un-stretched state, etc. it is generally at equilibrium, relaxed, etc. such that it applies little to no bias force (e.g., not pushing, not pulling, not applying stress, not applying strain, not applying tension, etc.).

FIG. 10B illustrates the wafer retaining device 100 in the open state, in accordance with some embodiments. In some embodiments, when the first lever 102 is in the first open position, the first spring of the first biasing member 108 is in an extended state. In some embodiments, when the first spring is in the extended state shown in FIG. 10B, the first spring exerts the first biasing force to the first lever 102 as a result of a length of the first spring being greater than an equilibrium length of the first spring, thereby resulting in a pulling force by the first spring to the first lever 102. In some embodiments, when the second lever 110 is in the second open position, the second spring of the second biasing member 142 is in an extended state. In some embodiments, when the second spring is in the extended state shown in FIG. 10B, the second spring exerts the second biasing force to the second lever 110 as a result of a length of the second spring being greater than an equilibrium length of the second spring, thereby resulting in a pulling force by the second spring to the second lever 110.

In some embodiments, the first biasing force applied by the first spring of the first biasing member 108 is greater when the first spring is in the extended state shown in FIG. 10B than when the first spring is in the uncompressed state shown in FIG. 10A.

In some embodiments, the second biasing force applied by the second spring of the second biasing member 142 is greater when the second spring is in the extended state shown in FIG. 10B than when the second spring is in the uncompressed state shown in FIG. 10A.

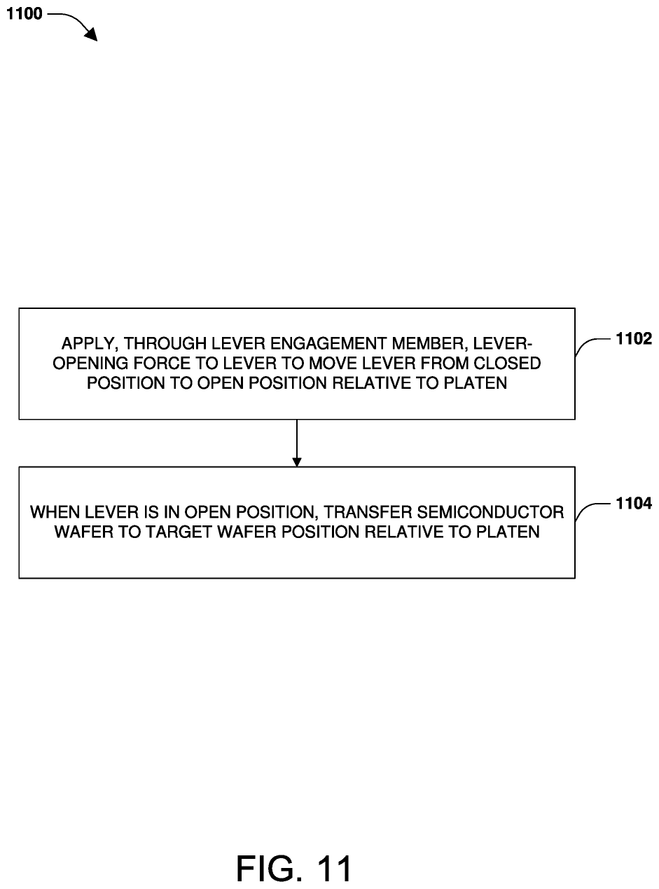

A method 1100 of a wafer retaining device, such as the wafer retaining device 100, is illustrated in FIG. 11 in accordance with some embodiments. The wafer retaining device comprises at least one of (i) a platen configured to support a semiconductor wafer, (ii) a retainer assembly comprising at least one of a mounting member coupled to the platen, a lever, or a biasing member configured to bias the lever to a closed position relative to the platen, or (iii) a lever engagement member configured to engage the lever. In some embodiments, at least one of (i) the platen comprises the platen 114, (ii) the semiconductor wafer comprises the semiconductor wafer 104, (iii) the retainer assembly comprises at least one of the first retainer assembly 152, the second retainer assembly 154, or the third retainer assembly, (iv) the mounting member comprises at least one of the first mounting member 106, the second mounting member 112, or the third mounting member, (v) the lever comprises at least one of the first lever 102, the second lever 110, or the third lever 402, (vi) the biasing member comprises at least one of the first biasing member 108, the second biasing member 142, or the third biasing member, or (vii) the lever engagement member comprises at least one of the first lever engagement member 120, the second lever engagement member 122, or the third lever engagement member. At 1102, a lever-opening force is applied, through the lever engagement member, to the lever to move the lever from the closed position to an open position relative to the platen. At 1104, when the lever is in the open position, the semiconductor wafer is transferred to a target wafer position relative to the platen. In some embodiments, the semiconductor wafer is transferred from a wafer storage device to the target wafer position relative to the platen.

In some embodiments, when the semiconductor wafer is in the target wafer position relative to the platen, a biasing force applied by the biasing member is used to move the lever to the closed position relative to the platen. In some embodiments, such as illustrated in FIG. 2C, the biasing force is applied by a spring of the biasing member that at least one of (i) has a length that is less than an equilibrium length of the spring, or (ii) applies a pushing force to the lever. In some embodiments, such as illustrated in FIG. 10B, the biasing force is applied by a spring of the biasing member that at least one of (i) has a length that is greater than an equilibrium length of the spring, or (ii) applies a pulling force to the lever. In some embodiments, the lever inhibits movement of the semiconductor wafer from the target wafer position when the lever is in the closed position.

In some embodiments, the lever does not obstruct a path of motion, such as the second path of motion 234, of the semiconductor wafer when the lever is in the open position. In some embodiments, the semiconductor wafer is transferred to the target wafer position by moving the semiconductor wafer along the path of motion to the target wafer position when the lever is in the open position. In some embodiments, when the lever is in the closed position, the lever obstructs the path of motion of the semiconductor wafer.

In some embodiments, the lever moves from the closed position to the open position when the lever-opening force overcomes a biasing force applied by the biasing member to the lever.

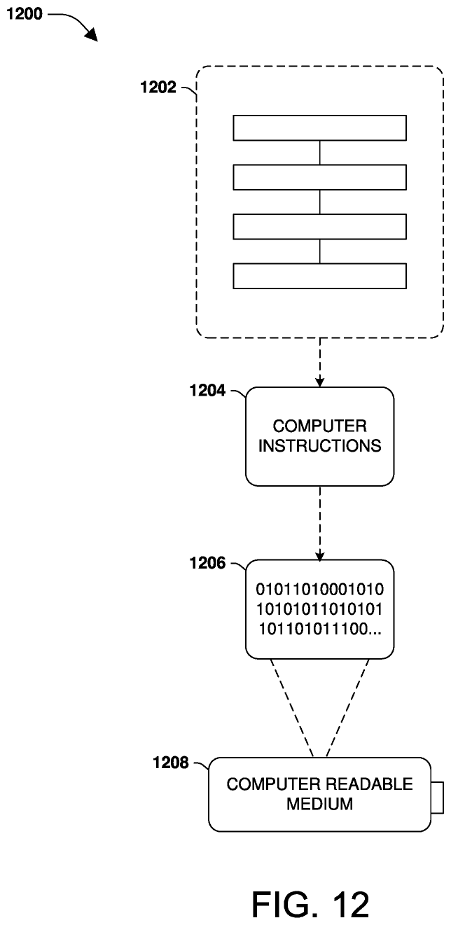

One or more embodiments involve a computer-readable medium comprising processor-executable instructions configured to implement one or more of the techniques presented herein. An exemplary computer-readable medium is illustrated in FIG. 12, wherein the embodiment 1200 comprises a computer-readable medium 1208 (e.g., a CD-R, DVD-R, flash drive, a platter of a hard disk drive, etc.), on which is encoded computer-readable data 1206. This computer-readable data 1206 in turn comprises a set of processor-executable computer instructions 1204 configured to implement one or more of the principles set forth herein when executed by a processor. In some embodiments 1200, the processor-executable computer instructions 1204 are configured to implement a method 1202, such as at least some of the aforementioned method(s) when executed by a processor. In some embodiments, the processor-executable computer instructions 1204 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a wafer retaining device is provided. The wafer retaining device includes a platen configured to support a semiconductor wafer, and a retainer assembly. The retainer assembly includes a mounting member coupled to the platen, a lever, and a biasing member including a first end coupled to the lever and a second end coupled to the mounting member. The biasing member is configured to bias the lever to a closed position relative to the platen. The lever inhibits movement of the semiconductor wafer when the lever is in the closed position.

In some embodiments, the wafer retaining device includes a lever engagement member configured to apply a lever-opening force to the lever to move the lever from the closed position to an open position relative to the platen.

In some embodiments, the lever obstructs a first path of motion of the semiconductor wafer when the lever is in the closed position, and the lever does not obstruct the first path of motion of the semiconductor wafer when the lever is in the open position.

In some embodiments, the lever moves from the closed position to the open position when the lever-opening force overcomes a biasing force applied by the biasing member to the lever.

In some embodiments, the wafer retaining device includes a hard stop device coupled to the platen and configured to separate the semiconductor wafer from a semiconductor processing component by at least a threshold distance.

In some embodiments, the semiconductor processing component includes a faraday cup configured to detect ions during an ion implantation process performed on the semiconductor wafer.

In some embodiments, the biasing member includes a spring.

In some embodiments, the lever includes a power region coupled to the first end of the biasing member, a weight region obstructing a path of motion of the semiconductor wafer when the lever is in the closed position, and a fulcrum region pivotally coupled to the mounting member.

In some embodiments, a wafer retaining device is provided. The wafer retaining device includes a platen configured to support a semiconductor wafer, a retainer assembly, and a lever engagement member. The retainer assembly includes a mounting member coupled to the platen and a lever including a weight region configured to inhibit movement of the semiconductor wafer when the lever is in a closed position relative to the platen, and a fulcrum region pivotally coupled to the mounting member. The lever engagement member is configured to apply a lever-opening force to the lever to move the lever from the closed position to an open position relative to the platen. The movement of the lever from the closed position to the open position includes rotation of the lever about an axis through the fulcrum region.

In some embodiments, the lever obstructs a first path of motion of the semiconductor wafer when the lever is in the closed position, and the lever does not obstruct the first path of motion of the semiconductor wafer when the lever is in the open position.

In some embodiments, the wafer retaining device includes a hard stop device coupled to the platen and configured to separate the semiconductor wafer from a semiconductor processing component by at least a threshold distance.

In some embodiments, the semiconductor processing component includes a faraday cup configured to detect ions during an ion implantation process performed on the semiconductor wafer.

In some embodiments, a method for operating a wafer retaining device is provided. The wafer retaining device includes (i) a platen configured to support a semiconductor wafer, (ii) a retainer assembly including a lever and a biasing member configured to bias the lever to a closed position relative to the platen, and (iii) a lever engagement member configured to engage the lever. The method includes applying, through the lever engagement member, a lever-opening force to the lever to move the lever from the closed position to an open position relative to the platen. The method includes when the lever is in the open position, transferring the semiconductor wafer to a target wafer position relative to the platen.

In some embodiments, the method includes when the semiconductor wafer is in the target wafer position relative to the platen, moving, using a biasing force applied by the biasing member to the lever, the lever to the closed position relative to the platen, wherein the lever inhibits movement of the semiconductor wafer from the target wafer position when the lever is in the closed position.

In some embodiments, the lever does not obstruct a path of motion of the semiconductor wafer when the lever is in the open position. Transferring the semiconductor wafer to the target wafer position includes moving the semiconductor wafer along the path of motion to the target wafer position when the lever is in the open position. The method includes when the lever is in the closed position, obstructing the path of motion of the semiconductor wafer using the lever.

In some embodiments, the lever moves from the closed position to the open position when the lever-opening force overcomes a biasing force applied by the biasing member to the lever.

In some embodiments, a wafer retaining device is provided. The wafer retaining device includes a platen configured to support a semiconductor wafer, a first retainer assembly, a second retainer assembly, and a lever engagement structure. The first retainer assembly includes a first mounting member coupled to the platen, and a first lever pivotally coupled to the first mounting member. The second retainer assembly includes a second mounting member coupled to the platen, and a second lever pivotally coupled to the second mounting member. The lever engagement structure includes a body, a first lever engagement member protruding from the body and configured to engage the first lever, and a second lever engagement member protruding from the body and configured to engage the second lever. The first lever inhibits movement of the semiconductor wafer when the first lever is in a first closed position relative to the platen. The second lever inhibits movement of the semiconductor wafer when the second lever is in a second closed position relative to the platen. The lever engagement structure is configured to concurrently apply, through the first lever engagement member, a first lever-opening force to the first lever to move the first lever from the first closed position to a first open position relative to the platen, and apply, through the second lever engagement member, a second lever-opening force to the second lever to move the second lever from the second closed position to a second open position relative to the platen.

In some embodiments, the first lever obstructs a first path of motion of the semiconductor wafer when the first lever is in the first closed position, the first lever does not obstruct the first path of motion of the semiconductor wafer when the first lever is in the first open position, the second lever obstructs the first path of motion of the semiconductor wafer when the second lever is in the second closed position, and the second lever does not obstruct the first path of motion of the semiconductor wafer when the second lever is in the second open position.

In some embodiments, the first retainer assembly includes a first biasing member including a first end coupled to the first lever and a second end coupled to the first mounting member, wherein the first biasing member is configured to bias the first lever to the first closed position, and the second retainer assembly includes a second biasing member including a first end coupled to the second lever and a second end coupled to the second mounting member, wherein the second biasing member is configured to bias the second lever to the second closed position.

In some embodiments, the first biasing member includes a first spring, and the second biasing member includes a second spring.

In some embodiments, the first lever moves from the first closed position to the first open position when the first lever-opening force overcomes a first biasing force applied by a first biasing member to the first lever, and the second lever moves from the second closed position to the second open position when the second lever-opening force overcomes a second biasing force applied by a second biasing member to the second lever.

In some embodiments, the wafer retaining device includes a hard stop device coupled to the platen and configured to separate the semiconductor wafer from a semiconductor processing component by at least a threshold distance.

In some embodiments, the semiconductor processing component includes a faraday cup configured to detect ions during an ion implantation process performed on the semiconductor wafer.

In some embodiments, the wafer retaining device includes a first protective structure at least partially surrounding the first lever, and a second protective structure at least partially surrounding the second lever.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A wafer retaining device, comprising:
a platen configured to support a semiconductor wafer; and
a retainer assembly comprising:
a mounting member coupled to the platen;
a lever; and
a biasing member comprising a first end coupled to the lever and a second end coupled to the mounting member,
wherein:
the biasing member is configured to bias the lever to a closed position relative to the platen; and
the lever inhibits movement of the semiconductor wafer when the lever is in the closed position.

2. The wafer retaining device of claim 1, comprising:
a lever engagement member configured to apply a lever-opening force to the lever to move the lever from the closed position to an open position relative to the platen.

3. The wafer retaining device of claim 2, wherein:
the lever obstructs a first path of motion of the semiconductor wafer when the lever is in the closed position; and
the lever does not obstruct the first path of motion of the semiconductor wafer when the lever is in the open position.

4. The wafer retaining device of claim 2, wherein:
the lever moves from the closed position to the open position when the lever-opening force overcomes a biasing force applied by the biasing member to the lever.

5. The wafer retaining device of claim 1, comprising:
a hard stop device coupled to the platen and configured to separate the semiconductor wafer from a semiconductor processing component by at least a threshold distance.

6. The wafer retaining device of claim 5, wherein:
the semiconductor processing component comprises a faraday cup configured to detect ions during an ion implantation process performed on the semiconductor wafer.

7. The wafer retaining device of claim 1, wherein:
the biasing member comprises a spring.

8. The wafer retaining device of claim 1, wherein the lever comprises:
a power region coupled to the first end of the biasing member;
a weight region obstructing a path of motion of the semiconductor wafer when the lever is in the closed position; and
a fulcrum region pivotally coupled to the mounting member.

9. A method of operating a wafer retaining device,
the wafer retaining device comprising:
a platen configured to support a semiconductor wafer;
a retainer assembly comprising a lever and a biasing member configured to bias the lever to a closed position relative to the platen; and
a lever engagement member configured to engage the lever; and
the method comprising:
applying, through the lever engagement member, a lever-opening force to the lever to move the lever from the closed position to an open position relative to the platen; and
when the lever is in the open position, transferring the semiconductor wafer to a target wafer position relative to the platen.

10. The method of claim 9, comprising:
when the semiconductor wafer is in the target wafer position relative to the platen, moving, using a biasing force applied by the biasing member to the lever, the lever to the closed position relative to the platen, wherein the lever inhibits movement of the semiconductor wafer from the target wafer position when the lever is in the closed position.

11. The method of claim 9, wherein:
the lever does not obstruct a path of motion of the semiconductor wafer when the lever is in the open position;
transferring the semiconductor wafer to the target wafer position comprises moving the semiconductor wafer along the path of motion to the target wafer position when the lever is in the open position; and
the method comprises when the lever is in the closed position, obstructing the path of motion of the semiconductor wafer using the lever.

12. The method of claim 9, wherein:
the lever moves from the closed position to the open position when the lever-opening force overcomes a biasing force applied by the biasing member to the lever.

13. A wafer retaining device, comprising:
a platen configured to support a semiconductor wafer;
a first retainer assembly comprising:
a first mounting member coupled to the platen; and
a first lever pivotally coupled to the first mounting member; and
a second retainer assembly comprising:
a second mounting member coupled to the platen; and
a second lever pivotally coupled to the second mounting member; and
a lever engagement structure comprising:
a body;
a first lever engagement member protruding from the body and configured to engage the first lever; and
a second lever engagement member protruding from the body and configured to engage the second lever,
wherein:
the first lever inhibits movement of the semiconductor wafer when the first lever is in a first closed position relative to the platen;
the second lever inhibits movement of the semiconductor wafer when the second lever is in a second closed position relative to the platen; and
the lever engagement structure is configured to concurrently:
apply, through the first lever engagement member, a first lever-opening force to the first lever to move the first lever from the first closed position to a first open position relative to the platen; and
apply, through the second lever engagement member, a second lever-opening force to the second lever to move the second lever from the second closed position to a second open position relative to the platen.

14. The wafer retaining device of claim 13, wherein:
the first lever obstructs a first path of motion of the semiconductor wafer when the first lever is in the first closed position;
the first lever does not obstruct the first path of motion of the semiconductor wafer when the first lever is in the first open position;
the second lever obstructs the first path of motion of the semiconductor wafer when the second lever is in the second closed position; and
the second lever does not obstruct the first path of motion of the semiconductor wafer when the second lever is in the second open position.

15. The wafer retaining device of claim 13, wherein:
the first retainer assembly comprises a first biasing member comprising a first end coupled to the first lever and a second end coupled to the first mounting member, wherein the first biasing member is configured to bias the first lever to the first closed position; and
the second retainer assembly comprises a second biasing member comprising a first end coupled to the second lever and a second end coupled to the second mounting member, wherein the second biasing member is configured to bias the second lever to the second closed position.

16. The wafer retaining device of claim 15, wherein:
the first biasing member comprises a first spring; and
the second biasing member comprises a second spring.

17. The wafer retaining device of claim 13, wherein:
the first lever moves from the first closed position to the first open position when the first lever-opening force overcomes a first biasing force applied by a first biasing member to the first lever; and
the second lever moves from the second closed position to the second open position when the second lever-opening force overcomes a second biasing force applied by a second biasing member to the second lever.

18. The wafer retaining device of claim 13, comprising:
a hard stop device coupled to the platen and configured to separate the semiconductor wafer from a semiconductor processing component by at least a threshold distance.

19. The wafer retaining device of claim 18, wherein:
the semiconductor processing component comprises a faraday cup configured to detect ions during an ion implantation process performed on the semiconductor wafer.

20. The wafer retaining device of claim 13, comprising:
a first protective structure at least partially surrounding the first lever; and
a second protective structure at least partially surrounding the second lever.
